(19) United States
(12) Patent Application Publication
(10) Pub. No.: US 2025/0105800 A1
(43) Pub. Date: Mar. 27, 2025

(54) METHODS AND APPARATUS TO IMPROVE AN OUTPUT OF AN AMPLIFIER

(71) Applicant: Texas Instruments Incorporated, Dallas, TX (US)

(72) Inventors: Hua Shao, Tucson, AZ (US); Paul Damitio, Tucson, AZ (US); Bharath Karthik Vasan, Tucson, AZ (US); Joel M. Halbert, Tucson, AZ (US)

(21) Appl. No.: 18/759,086

(22) Filed: Jun. 28, 2024

Related U.S. Application Data
(60) Provisional application No. 63/540,885, filed on Sep. 27, 2023.

(51) Int. Cl. H03F 3/04

(52) U.S. Cl. CPC H03F 3/04

(57) ABSTRACT

An example apparatus includes: first buffer circuitry having a first terminal and a second terminal; second buffer circuitry having a first terminal and a second terminal; third buffer circuitry having a first terminal and a second terminal, the first terminal of the third buffer circuitry coupled to the first terminal of the second buffer circuitry; a first transistor having a first terminal, a second terminal and a control terminal, the first terminal of the first transistor coupled to the first terminal of the first buffer circuitry, the control terminal of the first transistor coupled to the second terminal of the second buffer circuitry; a second transistor having a first terminal and a second terminal, the first terminal of the second transistor coupled to the second terminal of the first buffer circuitry.

### CROSS-REFERENCE TO RELATED APPLICATION

This patent application claims the benefit of and priority to U.S. Provisional Patent Application No. 63/540,885 filed Sep. 27, 2023, which is hereby incorporated herein by reference in its entirety.

### TECHNICAL FIELD

This description relates generally to amplifiers and, more particularly, to methods and apparatus to improve an output of an amplifier.

### BACKGROUND

As electronics continue to advance, systems have become capable of safely operating at increasingly complex operating conditions, such as higher powers and higher speeds. In amplifier circuitry, increasingly complex circuitry implements advanced techniques to support increasing output voltages, output currents, and speeds. Such circuitry allows the amplifier circuitry to precisely supply power to increasingly complex loads at higher speeds despite complex operating conditions.

### SUMMARY

For methods and apparatus to improve an output of an amplifier, an example amplifier includes input stage circuitry including: first buffer circuitry having a first terminal and a second terminal; second buffer circuitry having a first terminal and a second terminal; third buffer circuitry having a first terminal and a second terminal, the first terminal of the third buffer circuitry coupled to the first terminal of the second buffer circuitry; a first transistor having a first terminal, a second terminal and a control terminal, the first terminal of the first transistor coupled to the first terminal of the first buffer circuitry, the control terminal of the first transistor coupled to the second terminal of the second buffer circuitry; a second transistor having a first terminal, a second terminal, and a control terminal, the first terminal of the second transistor coupled to the second terminal of the first buffer circuitry, the control terminal of the second transistor coupled to the second terminal of the third buffer circuitry; and output stage circuitry having a first terminal and a second terminal, the first terminal of the output stage circuitry coupled to the second terminal of the first transistor, the second terminal of the output stage circuitry coupled to the second terminal of the second transistor. Other examples are described.

For methods and apparatus to improve an output of an amplifier, an example amplifier includes input stage circuitry having a first terminal and a second terminal; and output stage circuitry including: first current mirror circuitry having a first terminal and a second terminal, the first terminal of the first current mirror circuitry coupled to the first terminal of the input stage circuitry; second current mirror circuitry having a first terminal and a second terminal, the first terminal of the second current mirror circuitry coupled to the second terminal of the input stage circuitry; pre-driver circuitry having a terminal; first buffer circuitry having a first terminal and a second terminal; and second buffer circuitry having a first terminal and a second terminal, the first terminal of the second buffer circuitry is coupled to the first terminal of the first buffer circuitry; a first transistor having a first terminal, a second terminal, and a control terminal, the first terminal of the first transistor coupled to the second terminal of the first current mirror circuitry, the control terminal of the first transistor coupled to the second terminal of the first buffer circuitry; and a second transistor having a first terminal, a second terminal, and a control terminal, the first terminal of the second transistor coupled to the second terminal of the second current mirror circuitry, the second terminal of the second transistor coupled to the terminal of the pre-driver circuitry and the second terminal of the first transistor, the control terminal of the second transistor coupled to the second terminal of the second buffer circuitry. Other examples are described.

For methods and apparatus to improve an output of an amplifier, an example apparatus includes an input stage circuitry configured to: generate input operating points of an input voltage; and generate a reference current based on the input operating points; and output stage circuitry coupled to the input stage circuitry, the output stage circuitry configured to: generate a reference voltage based on the reference current; generate an output voltage based on the reference voltage; generate output operating points of the output voltage; and increase an output current of the output voltage responsive to the output operating points. Other examples are described.

### BRIEF DESCRIPTION OF THE DRAWINGS

FIG. 1 is a block diagram of an example power supply system including example amplifier circuitry structured to supply a relatively high voltage output to drive a capacitive load.

FIG. 2 is a schematic diagram of an example of the amplifier circuitry of FIG. 1 including example input stage circuitry and example output stage circuitry.

FIG. 3 is a schematic diagram of an example of the input stage circuitry of FIG. 2.

FIGS. 4A and 4B are a schematic diagram of an example of the output stage circuitry of FIG. 2 including example bootstrap buffer circuitry structured to improve output swing of the amplifier circuitry of FIGS. 1 and 2.

FIG. 5 is a schematic diagram of an example of the bootstrap buffer circuitry of FIGS. 4A and 4B.

FIG. 6 is a schematic diagram of another example of the amplifier circuitry of FIGS. 1 and 2.

FIG. 7 is a flowchart representative of example operations that may be at least one of executed, instantiated, or performed to implement the input stage circuitry of FIGS. 2 and 3, the output stage circuitry of FIGS. 2, 4A, 4B, and 5, or more generally the amplifier circuitry of FIGS. 1, 2, and 6.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

As electronics continue to advance, systems have become capable of safely operating at increasingly complex operating conditions, such as higher powers and higher speeds. In amplifier circuitry, increasingly complex circuitry implements advanced techniques to support increasing output voltages, output currents, and speeds. Such circuitry allows the amplifier circuitry to precisely supply power to increasingly complex loads at higher speeds despite complex operating conditions.

In some designs, amplifier circuitry is structured to supply power to complex loads including increasingly large capacitive elements. For example, in display testing systems, the amplifier circuitry generates large voltage pulses to drive a liquid-crystal display (LCD) panel, which has a relatively high capacitance. The amplifier circuitry accurately drives capacitive loads by generating output pulses that have large voltage swings and high slew rates (e.g., the slope of voltage changes versus time during transients). To support such complex outputs, amplifier circuitry continues to implement increasingly complex techniques.

In some designs, the amplifier circuitry uses circuitry to control a series of transistors that generate the output. To support relatively large voltage swings, the amplifier circuitry includes resistor dividers that distribute relatively large voltages across a plurality of transistors. The resistor dividers allow the amplifier circuitry to support relatively high output voltages using relatively lower voltage transistors, which have higher bandwidths in comparison to higher voltage transistors. However, stacking lower voltage transistors to support higher output voltages limits the output current in comparison to output currents that the higher voltage transistors support. Also, reducing the output current by using lower voltage transistors constrains the slew rate of the output of that amplifier circuitry, which results in an inferior transient response.

In other designs, the amplifier circuitry uses discrete unity gain operational amplifiers or high voltage transistors to bootstrap supply voltages of a signal path amplifier using the output. In such designs, the amplifier circuitry includes a first amplifier, a second amplifier, a third amplifier, and a resistor divider. The resistor divider divides supply voltages of the amplifier circuitry to generate a first reference voltage, which is between the high-side supply voltage and the output voltage, and a second reference voltage, which is between the low-side supply voltage and the output voltage. The first amplifier sets a high-side supply voltage of the second amplifier using the first reference voltage. The third amplifier sets a low-side supply voltage of the second amplifier using the second reference voltage. The second amplifier (also referred to as the signal path amplifier) drives the output of the amplifier circuitry using the first and second reference voltages. However, bootstrapping the second amplifier to the output using the first and third amplifiers has a relatively large footprint size, which creates thermal performance issues, stability issues, and an output current that is still limited by the second amplifier.

Examples described herein include methods and apparatus to improve the output of an amplifier by implementing bootstrapping techniques to increase voltage swing, currents, and slew-rates at the output of the amplifier. Circuitry structured to implement a bootstrapping technique have a feedback path from an output to an input, which creates an effectively high impedance input and improves input response. In some described examples, example amplifier circuitry includes input stage circuitry and output stage circuitry that implement bootstrapping techniques to support increasingly complex outputs. In the described examples, both the input stage circuitry and the output stage circuitry utilize current feedback to bootstrap the signal path and to boost the output current, support high output voltage swing, and high slew rates.

The input stage circuitry includes input buffer circuitry, bootstrap buffer circuitry, divider circuitry, and transistors. The input buffer circuitry receives an input voltage at an inverting input and a non-inverting input. The input buffer circuitry uses the input voltage to generate an auxiliary input voltage that is proportional to the input voltage. The divider circuitry generates first and second modulated input operating points by dividing the difference between the auxiliary input voltage and the supply voltages. The bootstrap buffer circuitry buffers the input operating points to control the bases of the transistors, which may be referred to as cascode transistors. The input buffer circuitry generates an input current representing the input voltage. Advantageously, the input stage circuitry generates the input current responsive to receiving the input voltage using the bootstrap buffer circuitry.

The output stage circuitry includes current mirror circuitry, pre-driver circuitry, bootstrap buffer circuitry, divider circuitry, and transistors. The current mirror circuitry mirrors the input current from the input stage circuitry. Some transistors supply replicas of the input current to the pre-driver circuitry (also referred to as gate driver circuitry). The output stage circuitry converts the input current to a reference input voltage at a high impedance terminal that the pre-driver circuitry uses to bias the output stage circuitry of the amplifier circuitry. The pre-driver circuitry also controls transistors to generate an auxiliary output voltage that is proportional to the output voltage. The divider circuitry generates first and second output operating points by dividing the difference between the auxiliary output voltage and the supply voltages. The bootstrap buffer circuitry buffers the output operating points to control the bases of the transistors, which may be referred to as cascode transistors. The transistors increase an output current at the output of the amplifier circuitry responsive to the bootstrap buffer circuitry supplying the output operating points. Advantageously, boosting the output current of the amplifier circuitry increases the slew rate and improves the transient response. Advantageously, the amplifier circuitry described herein supports complex outputs by using bootstrapping to support high output voltage swings and high output currents with a high slew rate and improved transient response.

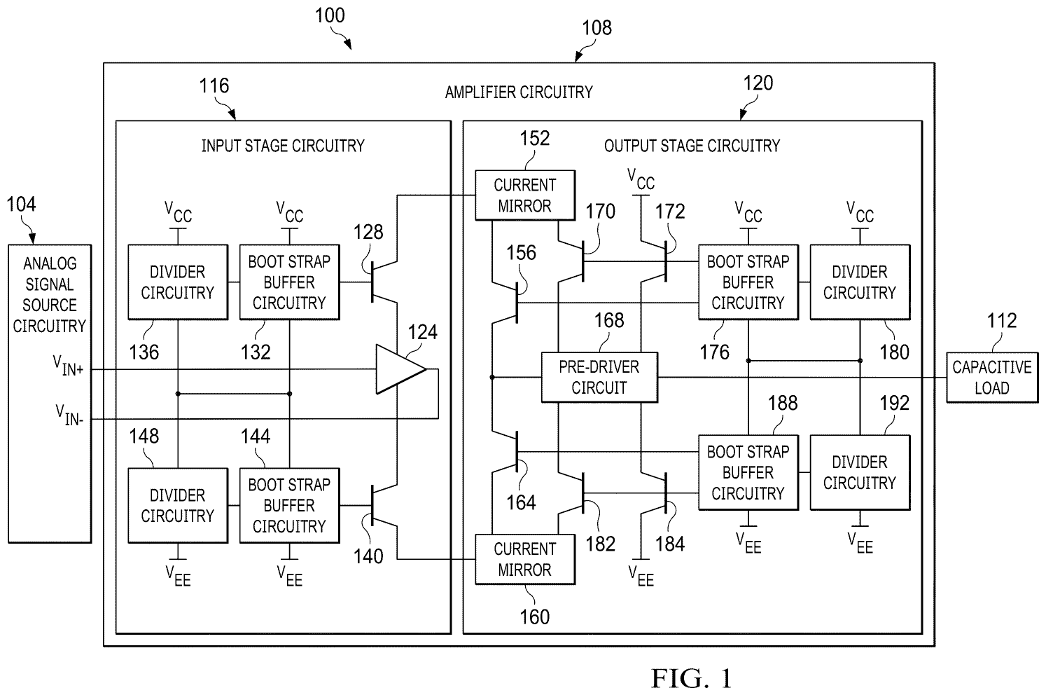

FIG. 1 is a block diagram of an example power supply system 100 including example analog signal source circuitry 104, example amplifier circuitry 108, and an example capacitive load 112. In the example of FIG. 1, the amplifier circuitry 108 includes input stage circuitry 116 and output stage circuitry 120. The example input stage circuitry 116 of FIG. 1 includes example input buffer circuitry 124, a first example transistor 128, first example bootstrap buffer circuitry 132, first example divider circuitry 136, a second example transistor 140, second example bootstrap buffer circuitry 144, and second example divider circuitry 148. The example output stage circuitry 120 of FIG. 1 includes first example current mirror circuitry 152, a third example transistor 156, second example current mirror circuitry 160, a fourth example transistor 164, example pre-driver circuitry 168, a fifth example transistor 170, a sixth example transistor 172, third example bootstrap buffer circuitry 176, third example divider circuitry 180, a seventh example transistor 182, an eighth example transistor 184, fourth example bootstrap buffer circuitry 188, and fourth example divider circuitry 192. In the example of FIG. 1, the amplifier circuitry 108 is structured to supply a relatively high complexity output to the capacitive load 112 responsive to a relatively less complex input from the analog signal source circuitry 104.

The analog signal source circuitry 104 has a first terminal and a second terminal that are coupled to the amplifier circuitry 108. In some examples, the analog signal source circuitry 104 is a type of programmable circuitry, such as a central processing unit (CPU), digital signal processor (DSP), etc. The amplifier circuitry 108 has a first terminal, a second terminal, and a third terminal. The first and second terminals (also referred to as input terminals) of the amplifier circuitry 108 are coupled to the analog signal source circuitry 104. The third terminal (also referred to as an output terminal) of the amplifier circuitry 108 is coupled to the capacitive load 112. In such examples, the analog signal source circuitry 104 is integrated (e.g., in the same package or apart of the same integrated circuit) as the amplifier circuitry 108. In other examples, the analog signal source circuitry 104 is external to the amplifier circuitry 108. In the example of FIG. 1, the analog signal source circuitry 104 is structured as external circuitry that supplies an input voltage to the amplifier circuitry 108. The capacitive load 112 has a terminal coupled to the amplifier circuitry 108. In some examples, the capacitive load 112 is external circuitry that has a capacitive element, such as an LCD panel. Alternatively, the amplifier circuitry 108 may be coupled to an alternative type of load having any combination of elements.

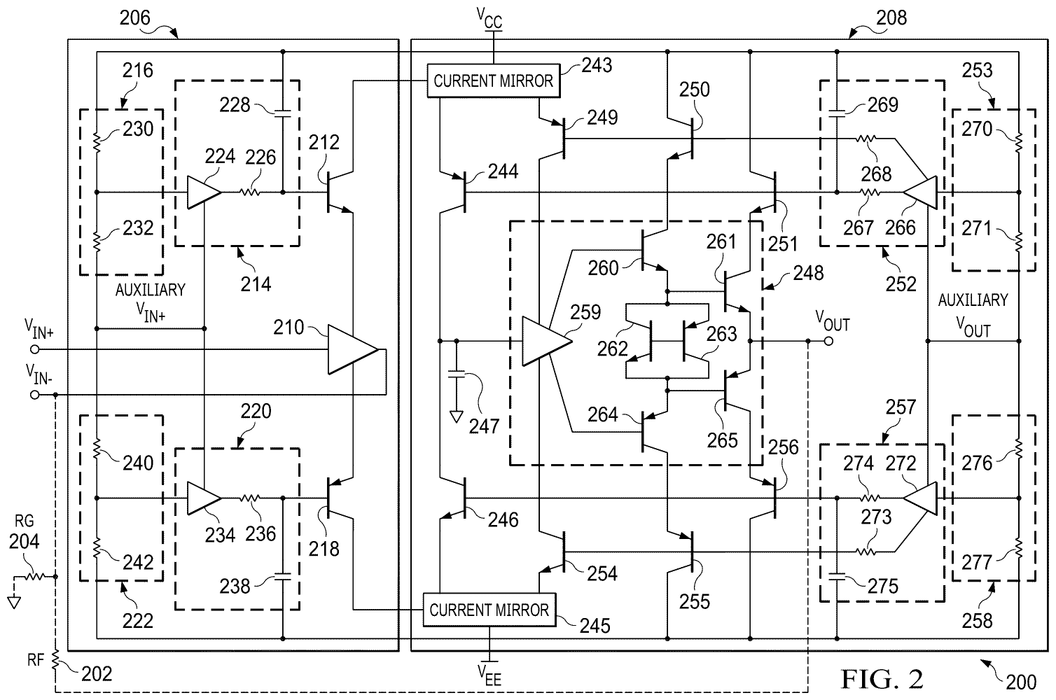

The input stage circuitry 116 has a first terminal, a second terminal, a third terminal, and a fourth terminal. The first and second terminals (also referred to as input terminals) of the input stage circuitry 116 are coupled to the analog signal source circuitry 104. The third and fourth terminals of the input stage circuitry 116 are coupled to the output stage circuitry 120. In the example of FIG. 1, the input stage circuitry 116 is structured as voltage to current converter circuitry, which generates a current as an output responsive to an input voltage. Examples of the input stage circuitry 116 are illustrated and described in connection with FIGS. 2, 3, and 6, below.

The output stage circuitry 120 has a first terminal, a second terminal, and a third terminal. The first and second terminals of the output stage circuitry 120 are coupled to the input stage circuitry 116. The third terminal (also referred to as an output terminal) of the output stage circuitry 120 is coupled to the capacitive load 112. In the example of FIG. 1, the output stage circuitry 120 is structured as current to voltage converter circuitry, which generates an output voltage responsive to an input current. Examples of the output stage circuitry 120 are illustrated and described in connection with FIGS. 2, 4A, 4B, 5, and 6, below.

The buffer circuitry 124 has a first terminal, a second terminal, a third terminal, and a fourth terminal. The first and second terminals of the buffer circuitry 124 are coupled to the analog signal source circuitry 104. The third terminal of the buffer circuitry 124 is coupled to the transistor 128. The fourth terminal of the buffer circuitry 124 is coupled to the transistor 140. Examples of the buffer circuitry 124 are illustrated and described in connection with FIGS. 2, 3, and 6, below.

The transistor 128 has a first terminal, a second terminal, and a control terminal. The first terminal of the transistor 128 is coupled to the buffer circuitry 124. The second terminal of the transistor 128 is coupled to the output stage circuitry 120. The control terminal of the transistor 128 is coupled to the buffer circuitry 132.

The buffer circuitry 132 has a first terminal, a second terminal, a third terminal, and a fourth terminal. The first terminal of the buffer circuitry 132 is coupled to a supply terminal, which supplies a high-side supply voltage (V_{CC}). In some examples, the power supply system 100 supports high-side supply voltages from negative twenty-five volts to positive thirty volts. The second terminal of the buffer circuitry 132 is coupled to the transistor 128. The third terminal of the buffer circuitry 132 is coupled to the divider circuitry 136. The fourth terminal of the buffer circuitry 132 is coupled to the divider circuitry 136, 148 and the buffer circuitry 144. Examples of the buffer circuitry 132 are illustrated and described in connection with FIGS. 2, 3, and 6, below.

The divider circuitry 136 has a first terminal, a second terminal, and a third terminal. The first terminal of the divider circuitry 136 is coupled to the supply terminal, which supplies the high-side supply voltage. The second terminal of the divider circuitry 136 is coupled to the buffer circuitry 132. The third terminal of the divider circuitry 136 is coupled to the buffer circuitry 132, 144 and the divider circuitry 148. Examples of the divider circuitry 136 are illustrated and described in connection with FIGS. 2, 3, and 6, below.

The transistor 140 has a first terminal, a second terminal, and a control terminal. The first terminal of the transistor 140 is coupled to the buffer circuitry 124. The second terminal of the transistor 140 is coupled to the output stage circuitry 120. The control terminal of the transistor 140 is coupled to the buffer circuitry 144.

The buffer circuitry 144 has a first terminal, a second terminal, a third terminal, and a fourth terminal. The first terminal of the buffer circuitry 144 is coupled to a common terminal, which supplies a low-side supply voltage (V_{EE}). In some examples, the power supply system 100 supports low-side supply voltages from positive twenty-five volts to negative thirty volts. In some such examples, the power supply system 100 supports the high and low supply voltages having a sixty-volt difference. The second terminal of the buffer circuitry 144 is coupled to the transistor 140. The third terminal of the buffer circuitry 144 is coupled to the divider circuitry 148. The fourth terminal of the buffer circuitry 144 is coupled to the buffer circuitry 132 and the divider circuitry 136, 148. Examples of the buffer circuitry 144 are illustrated and described in connection with FIGS. 2, 3, and 6, below.

The divider circuitry 148 has a first terminal, a second terminal, and a third terminal. The first terminal of the divider circuitry 148 is coupled to the common terminal, which supplies a low-side supply voltage. The second terminal of the divider circuitry 148 is coupled to the buffer circuitry 144. The third terminal of the divider circuitry 148 is coupled to the buffer circuitry 132, 144 and the divider circuitry 136. Examples of the divider circuitry 148 are illustrated and described in connection with FIGS. 2, 3, and 6, below.

The current mirror circuitry 152 has a first terminal, a second terminal, and a third terminal. The first terminal of the current mirror circuitry 152 is coupled to the input stage circuitry 116. The second terminal of the current mirror circuitry 152 is coupled to the transistor 156. The third terminal of the current mirror circuitry 152 is coupled to the transistor 170.

The transistor 156 has a first terminal, a second terminal, and a control terminal. The first terminal of the transistor 156 is coupled to the current mirror circuitry 152. The second terminal of the transistor 156 is coupled to the transistor 164 and the pre-driver circuitry 168. The control terminal of the transistor 156 is coupled to the buffer circuitry 176.

The current mirror circuitry 160 has a first terminal, a second terminal, and a third terminal. The first terminal of the current mirror circuitry 160 is coupled to the input stage circuitry 116. The second terminal of the current mirror circuitry 160 is coupled to the transistor 164. The third terminal of the current mirror circuitry 160 is coupled to the transistor 182.

The transistor 164 has a first terminal, a second terminal, and a control terminal. The first terminal of the transistor 164 is coupled to the transistor 156 and the pre-driver circuitry 168. The second terminal of the transistor 164 is coupled to the current mirror circuitry 160. The control terminal of the transistor 164 is coupled to the buffer circuitry 188.

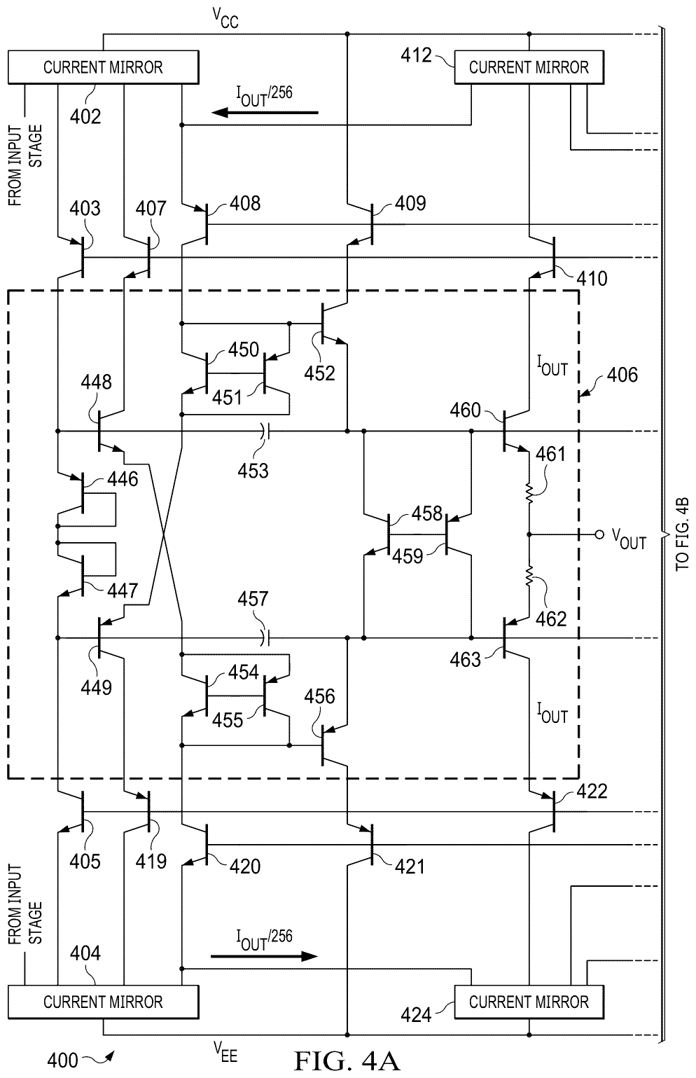

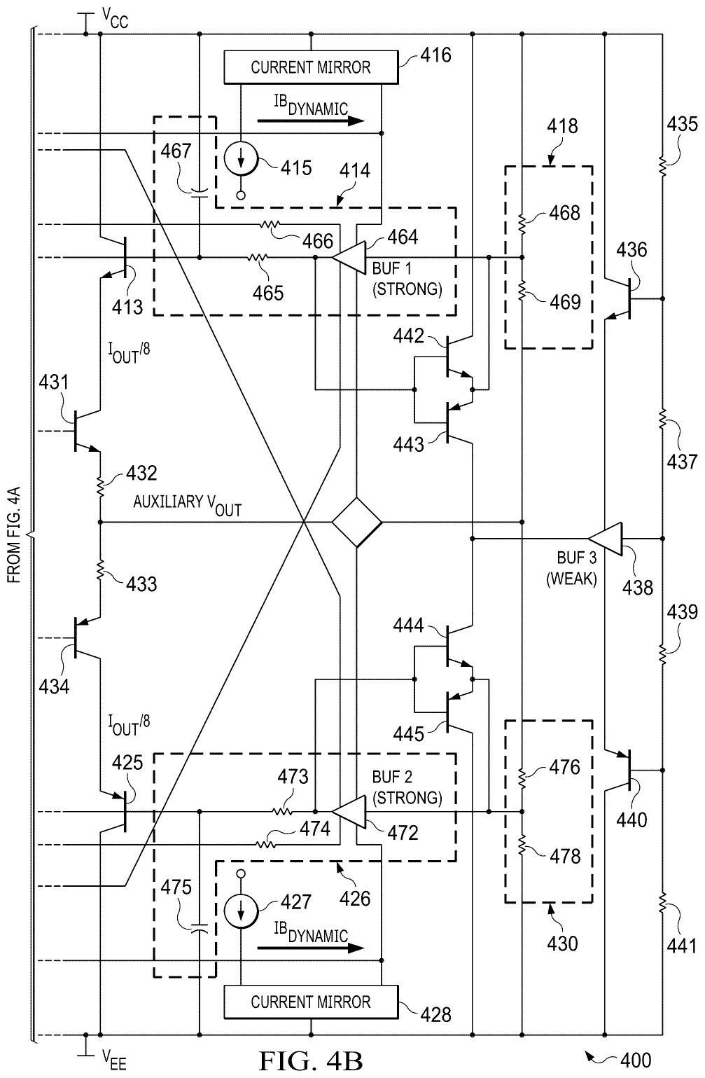

The pre-driver circuitry 168 has a first terminal, a second terminal, a third terminal, a fourth terminal, a fifth terminal, and a sixth terminal. The first terminal of the pre-driver circuitry 168 is coupled to the transistors 156, 164. The second terminal of the pre-driver circuitry 168 is coupled to the transistor 170. The third terminal of the pre-driver circuitry 168 is coupled to the transistor 172. The fourth terminal of the pre-driver circuitry 168 is coupled to the transistor 182. The fifth terminal of the pre-driver circuitry 168 is coupled to the transistor 184. The sixth terminal (also referred to as the output terminal) of the pre-driver circuitry 168 is coupled to the capacitive load 112. Examples of the pre-driver circuitry 168 are illustrated and described in connection with FIGS. 2 and 4, below.

The transistor 170 has a first terminal, a second terminal, and a control terminal. The first terminal of the transistor 170 is coupled to the current mirror circuitry 152. The second terminal of the transistor 170 is coupled to the pre-driver circuitry 168. The control terminal of the transistor 170 is coupled to the transistor 172 and the buffer circuitry 176.

The transistor 172 has a first terminal, a second terminal, and a control terminal. The first terminal of the transistor 172 is coupled to the supply terminal, which supplies the high-side supply voltage. The second terminal of the transistor 172 is coupled to the pre-driver circuitry 168. The control terminal of the transistor 172 is coupled to the transistor 170 and the buffer circuitry 176.

The buffer circuitry 176 has a first terminal, a second terminal, a third terminal, a fourth terminal, and a fifth terminal. The first terminal of the buffer circuitry 176 is coupled to the supply terminal, which supplies the high-side supply voltage. The second terminal of the buffer circuitry 176 is coupled to the transistor 156. The third terminal of the buffer circuitry 176 is coupled to the transistors 170, 172. The fourth terminal of the buffer circuitry 176 is coupled to the divider circuitry 180. The fifth terminal of the buffer circuitry 176 is coupled to the divider circuitry 180, 192 and the buffer circuitry 188. Examples of the buffer circuitry 176 are illustrated and described in connection with FIGS. 2, 4, and 5, below.

The divider circuitry 180 has a first terminal, a second terminal, and a third terminal. The first terminal of the divider circuitry 180 is coupled to the supply terminal, which supplies the high-side supply voltage. The second terminal of the divider circuitry 180 is coupled to the buffer circuitry 176. The third terminal of the divider circuitry 180 is coupled to the buffer circuitry 176, 188 and the divider circuitry 192. Examples of the divider circuitry 180 are illustrated and described in connection with FIGS. 2 and 4, below.

The transistor 182 has a first terminal, a second terminal, and a control terminal. The first terminal of the transistor 182 is coupled to the pre-driver circuitry 168. The second terminal of the transistor 182 is coupled to the current mirror circuitry 160. The control terminal of the transistor 182 is coupled to the transistor 184 and the buffer circuitry 188.

The transistor 184 has a first terminal, a second terminal, and a control terminal. The first terminal of the transistor 184 is coupled to the pre-driver circuitry 168. The second terminal of the transistor 184 is coupled to the common terminal, which supplies the low-side supply voltage. The control terminal of the transistor 184 is coupled to the transistor 182 and the buffer circuitry 188.

The buffer circuitry 188 has a first terminal, a second terminal, a third terminal, a fourth terminal, and a fifth terminal. The first terminal of the buffer circuitry 188 is coupled to the common terminal, which supplies the low-side supply voltage. The second terminal of the buffer circuitry 188 is coupled to the transistor 164. The third terminal of the buffer circuitry 188 is coupled to the transistors 182, 184. The fourth terminal of the buffer circuitry 188 is coupled to the divider circuitry 192. The fifth terminal of the buffer circuitry 188 is coupled to the buffer circuitry 176 and the divider circuitry 180, 192. Examples of the buffer circuitry 188 are illustrated and described in connection with FIGS. 2, 4, and 5, below.

The divider circuitry 192 has a first terminal, a second terminal, and a third terminal. The first terminal of the divider circuitry 192 is coupled to the common terminal, which supplies the low-side supply voltage. The second terminal of the divider circuitry 192 is coupled to the buffer circuitry 188. The third terminal of the divider circuitry 192 is coupled to the buffer circuitry 176, 188 and the divider circuitry 180. Examples of the divider circuitry 192 are illustrated and described in connection with FIGS. 2 and 4, below.

In the example of FIG. 1, the transistors 128, 164, 172, 182 are NPN bipolar junction transistors (BJTs). Alternatively, the transistors 128, 164, 172, 182 may be n-channel field-effect transistors (FETs), n-channel insulated-gate bipolar transistors (IGBTs), n-channel junction field effect transistors (JFETs), n-channel metal-oxide semiconductor field-effect transistors (MOSFETs) or, with slight modifications, p-type equivalent devices. In the example of FIG. 1, the transistors 140, 156, 170, 184 are PNP BJTs. Alternatively, the transistors 140, 156, 170, 184 may be p-channel FETs, p-channel IGBTs, p-channel JFETs, p-channel MOSFETs, or, with slight modifications, N-type equivalent devices. The transistors 128,140, 156, 164, 170, 172, 182, 184 may be depletion mode devices, drain-extended devices, enhancement mode devices, natural transistors or other type of device structure transistors. Furthermore, the transistors 128,140, 156, 164, 170, 172, 182, 184 may be implemented in/over a silicon substrate (Si), a silicon carbide substrate (SiC), a gallium nitride substrate (GaN) or a gallium arsenide substrate (GaAs).

FIG. 2 is a schematic diagram of example amplifier circuitry 200, which is an example of the amplifier circuitry 108 of FIG. 1. In the example of FIG. 2, the amplifier circuitry 200 includes a first feedback resistor 202, a second feedback resistor 204, input stage circuitry 206, and output stage circuitry 208. The example input stage circuitry 206 of FIG. 2 includes example input buffer circuitry 210, a first example transistor 212, first example bootstrap buffer circuitry 214, first example divider circuitry 216, a second example transistor 218, second example bootstrap buffer circuitry 220, and second example divider circuitry 222. The example buffer circuitry 214 of FIG. 2 includes first example buffer circuitry 224, a first example resistor 226, and a first example capacitor 228. The example divider circuitry 216 of FIG. 2 includes a second example resistor 230 and a third example resistor 232. The example buffer circuitry 220 of FIG. 2 includes second example buffer circuitry 234, a fourth example resistor 236, and a second example capacitor 238. The example divider circuitry 222 of FIG. 2 includes a fifth example resistor 240 and a sixth example resistor 242.

The example output stage circuitry 208 of FIG. 2 includes first example current mirror circuitry 243, a first example transistor 244, second example current mirror circuitry 245, a second example transistor 246, a first example capacitor 247, example pre-driver circuitry 248, a third example transistor 249, a fourth example transistor 250, a fifth example transistor 251, first example bootstrap buffer circuitry 252, first example divider circuitry 253, a sixth example transistor 254, a seventh example transistor 255, an eighth example transistor 256, second example bootstrap buffer circuitry 257, and second divider circuitry 258. The example pre-driver circuitry 248 of FIG. 2 includes first example buffer circuitry 259, a ninth example transistor 260, a tenth example transistor 261, an eleventh example transistor 262, a thirteenth example transistor 263, a fourteenth example transistor 264, and a fifteenth example transistor 265. The example buffer circuitry 252 of FIG. 2 includes second example buffer circuitry 266, a first example resistor 267, a second example resistor 268, and a second example capacitor 269. The example divider circuitry 253 of FIG. 2 includes a third example resistor 270 and a fourth example resistor 271. The example buffer circuitry 257 of FIG. 2 includes third example buffer circuitry 272, a fifth example resistor 273, a sixth example resistor 274, and a third example capacitor 275. The example divider circuitry 258 of FIG. 2 includes a seventh example resistor 276 and an eighth example resistor 277.

The resistor 202 has a first terminal and a second terminal. The first terminal of the resistor 202 is coupled to the resistor 204 and the input stage circuitry 206. The second terminal of the resistor 202 is coupled to the output stage circuitry 208. The resistor 204 has a first terminal and a second terminal. The first terminal of the resistor 204 is coupled to the resistor 202 and the input stage circuitry 206. The second terminal of the resistor 204 is coupled to a common terminal, which supplies a common potential (e.g., ground). In the example of FIG. 2, the resistors 202, 204 are structured as a feedback network, which have resistances that set the gain of the amplifier circuitry 200. Although in the example of FIG. 2, the resistors 202, 204 are illustrated external to the amplifier circuitry 200, in some examples the resistors 202, 204 are internal to the amplifier circuitry 200. In such examples, the amplifier circuitry 200 is structured as an open-loop amplifier. Also, in other examples, the resistors 202, 204 are not included in the system.

The input stage circuitry 206 is coupled to the resistors 202, 204 and the output stage circuitry 208. In some examples, such as in FIG. 1, the input stage circuitry 206 is coupled to the analog signal source circuitry 104 of FIG. 1, which supplies analog input signals. The input stage circuitry 206 is an example of the input stage circuitry 116 of FIG. 1. The output stage circuitry 208 is coupled to the resistor 202 and the input stage circuitry 206. In some examples, such as in FIG. 1, the output stage circuitry 208 is coupled to a load, such as the capacitive load 112 of FIG. 1. The output stage circuitry 208 is an example of the output stage circuitry 120 of FIG. 1. In the example of FIG. 2, the input stage circuitry 206 and the output stage circuitry 208 are structured as the amplifier circuitry 200.

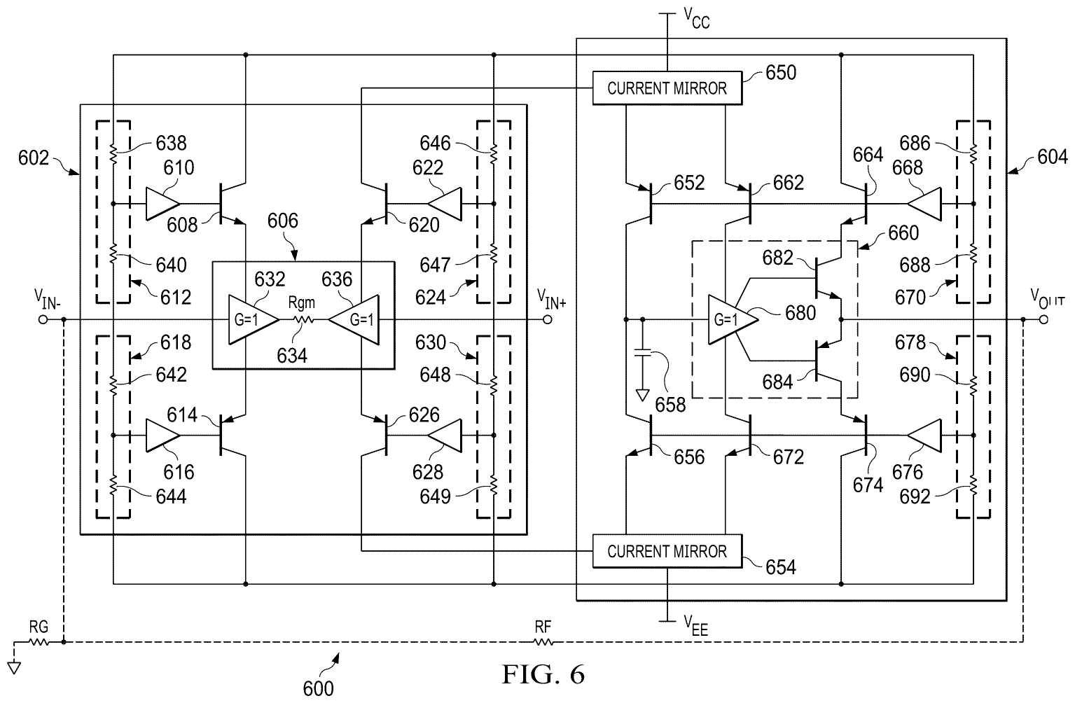

The buffer circuitry 210 is coupled to a non-inverting input terminal (V_{IN+}), which supplies a first input voltage, an inverting input terminal (V_{IN-}), which supplies a second input voltage, and the transistors 212, 218. In some examples, external circuitry (e.g., the analog signal source circuitry 104 of FIG. 1) is structured to supply an input voltage to the buffer circuitry 210 by setting the non-inverting and inverting input terminals. The buffer circuitry 210 is an example of the buffer circuitry 124 of FIG. 1. Another example of the buffer circuitry 210 is illustrated and described in connection with FIG. 6, below.

The transistor 212 is coupled to the output stage circuitry 208 and the buffer circuitry 210, 214. The transistor 212 is an example of the transistor 128 of FIG. 1. The buffer circuitry 214 is coupled to the transistor 212, the divider circuitry 216, 222, and the buffer circuitry 220. The buffer circuitry 214 is an example of the buffer circuitry 132 of FIG. 1. The divider circuitry 216 is coupled to the buffer circuitry 214, 220 and the divider circuitry 222. The divider circuitry 216 is an example of the divider circuitry 136 of FIG. 1.

The transistor 218 is coupled to the output stage circuitry 208 and the buffer circuitry 210, 220. The transistor 218 is an example of the transistor 140 of FIG. 1. The buffer circuitry 220 is coupled to the transistor 218, the buffer circuitry 214, and the divider circuitry 216, 222. The buffer circuitry 220 is an example of the buffer circuitry 144 of FIG. 1. The divider circuitry 222 is coupled to the buffer circuitry 214, 220 and the divider circuitry 216. The divider circuitry 222 is an example of the divider circuitry 148 of FIG. 1.

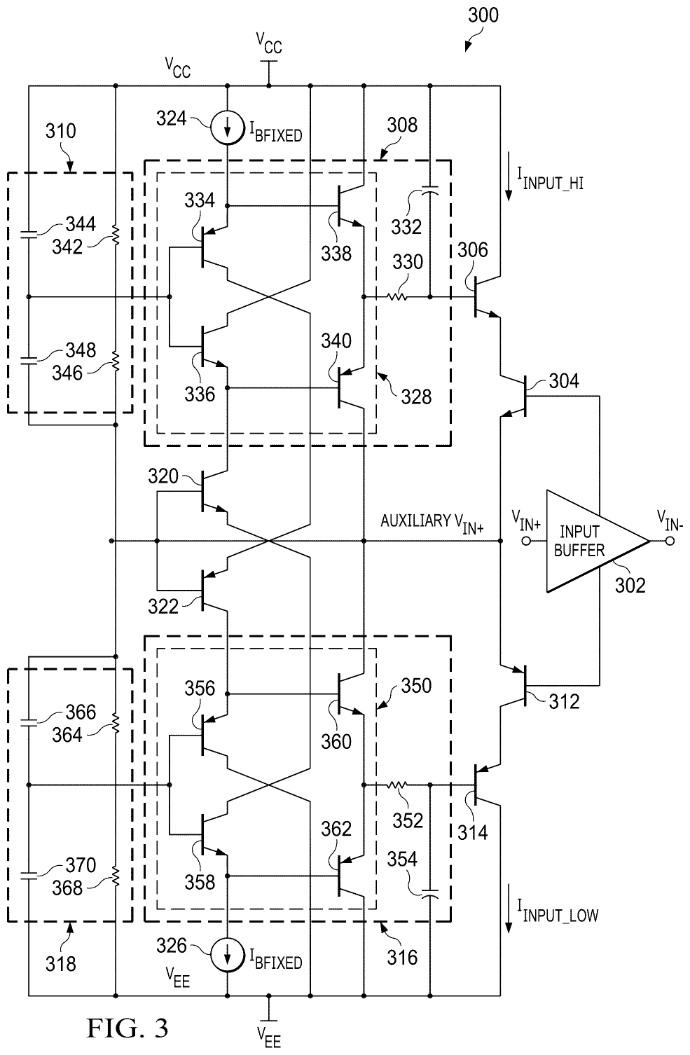

The buffer circuitry 224 has a first terminal, a second terminal, and a third terminal. The first terminal of the buffer circuitry 224 is coupled to the divider circuitry 216. The second terminal of the buffer circuitry 224 is coupled to the resistor 226. The third terminal of the buffer circuitry 224 is coupled to the divider circuitry 216, 222 and the buffer circuitry 220. An example of the buffer circuitry 224 is illustrated and described in connection with FIG. 3, below. The resistor 226 has a first terminal and a second terminal. The first terminal of the resistor 226 is coupled to the buffer circuitry 224. The second terminal of the resistor 226 is coupled to the transistor 212 and the capacitor 228. The capacitor 228 has a first terminal and a second terminal. The first terminal of the capacitor 228 is coupled to the supply terminal, which supplies the high-side supply voltage. The second terminal of the capacitor 228 is coupled to the transistor 212 and the resistor 226. The resistor 226 and the capacitor 228 are structured as low-pass filtering circuitry, which has a corner frequency that suppresses relatively high-frequency transients to improve settling responses at the output of the buffer circuitry 224.

The resistor 230 has a first terminal and a second terminal. The first terminal of the resistor 230 is coupled to the supply terminal, which supplies the high-side supply voltage. The second terminal of the resistor 230 is coupled to the buffer circuitry 214 and the resistor 232. The resistor 232 has a first terminal and a second terminal. The first terminal of the resistor 232 is coupled to the buffer circuitry 214 and the resistor 230. The second terminal of the resistor 232 is coupled to the buffer circuitry 214, 220 and the divider circuitry 222. The resistors 230, 232 are structured as a voltage divider, which sets an input of the buffer circuitry 214 to a voltage that is half-way between an auxiliary input voltage and the high-side supply voltage. The auxiliary input voltage is a replica of the non-inverting input terminal of the buffer circuitry 210. An example of the auxiliary input voltage is further described in connection with FIG. 3, below.

The buffer circuitry 234 has a first terminal, a second terminal, and a third terminal. The first terminal of the buffer circuitry 234 is coupled to the divider circuitry 222. The second terminal of the buffer circuitry 234 is coupled to the resistor 236. The third terminal of the buffer circuitry 234 is coupled to the buffer circuitry 214 and the divider circuitry 216, 222. An example of the buffer circuitry 234 is illustrated and described in connection with FIG. 3, below. The resistor 236 has a first terminal and a second terminal. The first terminal of the resistor 236 is coupled to the buffer circuitry 234. The second terminal of the resistor 236 is coupled to the transistor 218 and the capacitor 238. The capacitor 238 has a first terminal and a second terminal. The first terminal of the capacitor 238 is coupled to the common potential, which supplies the low-side supply voltage. The second terminal of the capacitor 238 is coupled to the transistor 218 and the resistor 236. The resistor 236 and the capacitor 238 are structured as low-pass filtering circuitry, which has a corner frequency that suppresses relatively high-frequency transients to improve settling responses at the output of the buffer circuitry 234.

The resistor 240 has a first terminal and a second terminal. The first terminal of the resistor 240 is coupled to the buffer circuitry 214, 220 and the divider circuitry 216. The second terminal of the resistor 240 is coupled to the buffer circuitry 220 and the resistor 242. The resistor 242 has a first terminal and a second terminal. The first terminal of the resistor 242 is coupled to the buffer circuitry 220 and the resistor 240. The second terminal of the resistor 242 is coupled to the common terminal, which supplies the low-side supply voltage. The resistors 240, 242 are structured as a voltage divider, which sets an input of the buffer circuitry 220 to a voltage that is half-way between the low-side supply voltage and the auxiliary input voltage.

The current mirror circuitry 243 is coupled to the input stage circuitry 206 and the transistors 244, 249. The current mirror circuitry 243 is an example of the current mirror circuitry 152 of FIG. 1. The transistor 244 is coupled to the current mirror circuitry 243, the transistors 246, 251, the capacitor 247, the pre-driver circuitry 248, and the buffer circuitry 252. The transistor 244 is an example of the transistor 156 of FIG. 1.

The current mirror circuitry 245 is coupled to the input stage circuitry 206 and the transistors 246, 254. The current mirror circuitry 245 is an example of the current mirror circuitry 160 of FIG. 1 The transistor 246 is coupled to the current mirror circuitry 243, the transistors 244, 256, the capacitor 247, the pre-driver circuitry 248, and the buffer circuitry 257. The transistor 246 is an example of the transistor 164 of FIG. 1.

The capacitor 247 has a first terminal and a second terminal. The first terminal of the capacitor 247 is coupled to the transistors 244, 246 and the pre-driver circuitry 248. The second terminal of the capacitor 247 is coupled to the common terminal, which supplies the common potential (e.g., ground). In the example of FIG. 2, the capacitor 247 is structured as current to voltage converter circuitry, which generates a reference voltage responsive to currents from the transistors 244, 246.

The pre-driver circuitry 248 is coupled to the transistors 244, 246, 249, 250, 251, 254, 255, 256 and the capacitor 247. In some examples, such as FIG. 1, the pre-driver circuitry 248 is coupled to a load, such as the capacitive load 112 of FIG. 1. The pre-driver circuitry 248 is an example of the pre-driver circuitry 168 of FIG. 1. Another example of the pre-driver circuitry 248 is illustrated and described in connection with FIG. 4B, below.

The transistor 249 is coupled to the current mirror circuitry 243, the pre-driver circuitry 248, the transistor 250, and the buffer circuitry 252. The transistor 249 is an example of the transistor 170 of FIG. 1. The transistor 250 is coupled to the supply terminal, which supplies the high-side supply voltage, the pre-driver circuitry 248, the transistor 249, and the buffer circuitry 252. The transistor 250 is an example of the transistor 172 of FIG. 1.

The transistor 251 has a first terminal, a second terminal, and a control terminal. The first terminal of the transistor 251 is coupled to the supply terminal, which supplies the high-side supply voltage. The second terminal of the transistor 251 is coupled to the pre-driver circuitry 248. The control terminal of the transistor 251 is coupled to the transistor 244 and the buffer circuitry 252.

The buffer circuitry 252 is coupled to the transistors 244, 249, 250, 251, the divider circuitry 253, 258, and the buffer circuitry 257. The buffer circuitry 252 is an example of the buffer circuitry 176 of FIG. 1. The divider circuitry 253 is coupled to the buffer circuitry 252, 257 and the divider circuitry 258. The divider circuitry 253 is an example of the divider circuitry 180 of FIG. 1.

The transistor 254 is coupled to the current mirror circuitry 245, the pre-driver circuitry 248, the transistor 255, and the buffer circuitry 257. The transistor 254 is an example of the transistor 182 of FIG. 1. The transistor 255 is coupled to the common terminal, which supplies the low-side supply voltage, the pre-driver circuitry 248, and the buffer circuitry 257. The transistor 255 is an example of the transistor 182 of FIG. 1.

The transistor 256 has a first terminal, a second terminal, and a control terminal. The first terminal of the transistor 256 is coupled to the pre-driver circuitry 248. The second terminal of the transistor 256 is coupled to the common terminal, which supplies the low-side supply voltage. The control terminal of the transistor 256 is coupled to the transistor 246 and the buffer circuitry 257.

The buffer circuitry 257 is coupled to the transistors 246, 254, 256, 255, the buffer circuitry 252, and the divider circuitry 253, 258. The buffer circuitry 257 is an example of the buffer circuitry 188 of FIG. 1. The divider circuitry 258 is coupled to the buffer circuitry 252, 257 and the divider circuitry 253. The divider circuitry 258 is an example of the divider circuitry 192 of FIG. 1.

The buffer circuitry 259 has a first terminal, a second terminal, a third terminal, a fourth terminal, and a fifth terminal. The first terminal of the buffer circuitry 259 is coupled to the transistors 244, 246 and the capacitor 247. The second terminal of the buffer circuitry 259 is coupled to the transistor 249. The third terminal of the buffer circuitry 259 is coupled to the transistor 254. The fourth terminal of the buffer circuitry 259 is coupled to the transistor 260. The fifth terminal of the buffer circuitry 259 is coupled to the transistor 264. An example of the buffer circuitry 259 is illustrated and described in connection with FIG. 4B, below.

The transistor 260 has a first terminal, a second terminal, and a control terminal. The first terminal of the transistor 260 is coupled to the transistor 250. The second terminal of the transistor 260 is coupled to the transistors 261, 262, 263. The control terminal of the transistor 260 is coupled to the buffer circuitry 259. The transistor 261 has a first terminal, a second terminal, and a control terminal. The first terminal of the transistor 261 is coupled to the transistor 251. The second terminal of the transistor 261 is coupled to the transistor 265 and the output terminal of the amplifier circuitry 200. The control terminal of the transistor 261 is coupled to the transistors 260, 262, 263.

The transistor 262 has a first terminal, a second terminal, and a control terminal. The first terminal of the transistor 262 is coupled to the transistors 260, 261, 263. The second terminal of the transistor 262 is coupled to the transistors 263, 264, 265. The control terminal of the transistor 262 is coupled to the transistor 263. The transistor 263 has a first terminal, a second terminal, and a control terminal. The first terminal of the transistor 263 is coupled to the transistors 260, 261, 262. The second terminal of the transistor 263 is coupled to the transistors 262, 264, 265. The control terminal of the transistor 263 is coupled to the transistor 262. The transistors 262, 263 are structured as diode circuitry, which regulates a direction of current flow.

The transistor 264 has a first terminal, a second terminal, and a control terminal. The first terminal of the transistor 264 is coupled to the transistors 262, 263, 265. The second terminal of the transistor 264 is coupled to the transistor 255. The control terminal of the transistor 264 is coupled to the buffer circuitry 259. The transistor 265 has a first terminal, a second terminal, and a control terminal. The first terminal of the transistor 265 is coupled to the transistor 261 and the output terminal of the amplifier circuitry 200. The second terminal of the transistor 265 is coupled to the transistor 256. The control terminal of the transistor 265 is coupled to the transistors 262, 263, 264.

The buffer circuitry 266 has a first terminal, a second terminal, a third terminal, and a fourth terminal. The first terminal of the buffer circuitry 266 is coupled to the divider circuitry 253. The second terminal of the buffer circuitry 266 is coupled to the resistor 267. The third terminal of the buffer circuitry 266 is coupled to the resistor 268. The fourth terminal of the buffer circuitry 266 is coupled to the divider circuitry 253, 258 and the buffer circuitry 257.

The resistor 267 has a first terminal and a second terminal. The first terminal of the resistor 267 is coupled to the buffer circuitry 266. The second terminal of the resistor 267 is coupled to the transistors 244, 251 and the capacitor 269. The resistor 268 has a first terminal and a second terminal. The first terminal of the resistor 268 is coupled to the buffer circuitry 266. The second terminal of the resistor 268 is coupled to the transistors 249, 250. The capacitor 269 has a first terminal and a second terminal. The first terminal of the capacitor 269 is coupled to the supply terminal, which supplies the high-side supply voltage. The second terminal of the capacitor 269 is coupled to the transistors 244, 251 and the resistor 267. The resistor 267 and the capacitor 269 are structured as timing circuitry, which has a timing constant that suppresses relatively high-frequency transients to improve settling times at the output of the buffer circuitry 266.

The resistor 270 has a first terminal and a second terminal. The first terminal of the resistor 270 is coupled to the supply terminal, which supplies the high-side supply voltage. The second terminal of the resistor 270 is coupled to the buffer circuitry 252 and the resistor 271. The resistor 271 has a first terminal and a second terminal. The first terminal of the resistor 271 is coupled to the buffer circuitry 252 and the resistor 270. The second terminal of the resistor 271 is coupled to the buffer circuitry 252, 257 and the divider circuitry 258. The resistors 270, 271 are structured to set an input of the buffer circuitry 252 to a voltage that is half-way between an auxiliary output voltage and the high-side supply voltage. The auxiliary output voltage is a replica of the output voltage at the output terminal of the amplifier circuitry 200. An example of the auxiliary output voltage is further described in connection with FIG. 4B, below.

The buffer circuitry 272 has a first terminal, a second terminal, a third terminal, and a fourth terminal. The first terminal of the buffer circuitry 272 is coupled to the divider circuitry 258. The second terminal of the buffer circuitry 272 is coupled to the resistor 273. The third terminal of the buffer circuitry 272 is coupled to the resistor 274. The fourth terminal of the buffer circuitry 272 is coupled to the buffer circuitry 252 and the divider circuitry 253, 258.

The resistor 273 has a first terminal and a second terminal. The first terminal of the resistor 273 is coupled to the buffer circuitry 272. The second terminal of the resistor 273 is coupled to the transistors 254, 255. The resistor 274 has a first terminal and a second terminal. The first terminal of the resistor 274 is coupled to the buffer circuitry 272. The second terminal of the resistor 274 is coupled to the transistors 246, 256 and the capacitor 275. The capacitor 275 has a first terminal and a second terminal. The first terminal of the capacitor 275 is coupled to the transistors 246, 256 and the resistor 274. The second terminal of the capacitor 275 is coupled to the common terminal, which supplies the low-side supply voltage. The resistor 274 and the capacitor 275 are structured as timing circuitry, which has a timing constant that suppresses relatively high-frequency transients to improve settling times at the output of the buffer circuitry 272.

The resistor 276 has a first terminal and a second terminal. The first terminal of the resistor 276 is coupled to the buffer circuitry 252, 257 and the divider circuitry 253, 258. The second terminal of the resistor 276 is coupled to the buffer circuitry 257 and the resistor 277. The resistor 277 has a first terminal and a second terminal. The first terminal of the resistor 277 is coupled to the buffer circuitry 257 and the resistor 276. The second terminal of the resistor 277 is coupled to the common terminal, which supplies the low-side supply voltage. The resistors 276, 277 are structured to set an input of the buffer circuitry 257 to a voltage that is half-way between the auxiliary output voltage and the low-side supply voltage.

In the example of FIG. 2, the transistors 212, 246, 250, 251, 254, 260, 261, 262 are NPN BJTs. Alternatively, the transistors 212, 246, 250, 251, 254, 260, 261, 262 may be n-channel FETs, n-channel IGBTs, n-channel JFETs, n-channel MOSFETs, or, with slight modifications, p-type equivalent devices. In the example of FIG. 2, the transistors 218, 244, 249, 255, 256, 263, 264, 265 are PNP BJTs. Alternatively, the transistors 218, 244, 249, 255, 256, 263, 264, 265 may be p-channel FETs, p-channel IGBTs, p-channel JFETs, p-channel MOSFETs, or, with slight modifications, N-type equivalent devices. The transistors 212, 218, 244, 246, 249, 250, 251, 254, 256, 260, 261, 262, 263, 264, 265 may be depletion mode devices, drain-extended devices, enhancement mode devices, natural transistors or other type of device structure transistors. Furthermore, the transistors 212, 218, 244, 246, 249, 250, 251, 254, 256, 260, 261, 262, 263, 264, 265 may be implemented in/over a silicon substrate (Si), a silicon carbide substrate (SiC), a gallium nitride substrate (GaN) or a gallium arsenide substrate (GaAs).

FIG. 3 is a schematic diagram of example input stage circuitry 300, which is an example implementation of the input stage circuitry 116, 206 of FIGS. 1 and 2. In the example of FIG. 3, the input stage circuitry 300 includes input buffer circuitry 302, a first transistor 304, a second transistor 306, first bootstrap buffer circuitry 308, first divider circuitry 310, a third transistor 312, a fourth transistor 314, second bootstrap buffer circuitry 316, second divider circuitry 318, a fifth transistor 320, a sixth transistor 322, first current source circuitry 324, and second current source circuitry 326. The example buffer circuitry 308 of FIG. 3 includes first example buffer circuitry 328, a first example resistor 330, and a first example capacitor 332. The example buffer circuitry 328 of FIG. 3 includes a seventh example transistor 334, an eighth example transistor 336, a ninth example transistor 338, and a tenth example transistor 340. The example divider circuitry 310 of FIG. 3 includes a second example resistor 342, a second example capacitor 344, a third example resistor 346, and a third example capacitor 348. The example buffer circuitry 316 of FIG. 3 includes second example buffer circuitry 350, a fourth example resistor 352, and a fourth example capacitor 354. The example buffer circuitry 350 of FIG. 3 includes an eleventh example transistor 356, a twelfth example transistor 358, a thirteenth example transistor 360, and a fourteenth example transistor 362. The example divider circuitry 318 of FIG. 3 includes a sixth example resistor 364, a sixth example capacitor 366, a seventh example resistor 368, and a seventh example capacitor 370.

The buffer circuitry 302 has a first terminal, a second terminal, a third terminal, and a fourth terminal. The first terminal of the buffer circuitry 302 is coupled to a non-inverting input terminal, which supplies a first input voltage (V_{IN+}). The second terminal of the buffer circuitry 302 is coupled to an inverting input terminal, which supplies a second input voltage (V_{IN-}). In the example of FIG. 3, the first and second input voltages are structured to represent inputs of the amplifier circuitry 108, 200 of FIGS. 1 and 2. The third terminal of the buffer circuitry 302 is coupled to the transistor 304. The fourth terminal of the buffer circuitry 302 is coupled to the transistor 312. The buffer circuitry 302 is another example of the buffer circuitry 124, 210 of FIGS. 1 and 2.

The transistor 304 has a first terminal, a second terminal, and a control terminal. The first terminal of the transistor 304 is coupled to the transistor 306. The second terminal of the transistor 304 is coupled to an auxiliary input terminal, which supplies an auxiliary input voltage (auxiliary V_{IN+}). The auxiliary input voltage is a voltage that is proportional to the voltage difference between the first and second input voltages (also referred to as the input voltage). In example operation, the auxiliary input voltage is approximately equal to the input voltage of the amplifier circuitry 108, 200. The control terminal of the transistor 304 is coupled to the buffer circuitry 302. The transistor 306 has a first terminal, a second terminal, and a control terminal. The first terminal of the transistor 306 is coupled to the supply terminal, which supplies the high-side supply voltage. The second terminal of the transistor 306 is coupled to the transistor 304. The control terminal of the transistor 306 is coupled to the buffer circuitry 308. In the example of FIG. 3, the transistors 304, 306 are structured to source a high-side input current (I_{INPUT_HI}) from the supply terminal. In the examples of FIGS. 1 and 2, the current mirror circuitry 152, 243 are structured to mirror the high-side input current. In such examples, the current mirror circuitry 152, 243 may be coupled between the transistor 306 and the supply terminal.

The buffer circuitry 308 is coupled to the transistors 306, 320, 322, the current source circuitry 324, the supply terminal, which supplies the high-side supply voltage, and the auxiliary input terminal, which supplies the auxiliary input voltage. The buffer circuitry 308 is another example of the buffer circuitry 132, 214 of FIGS. 1 and 2. The divider circuitry 310 is coupled to the buffer circuitry 308, the supply terminal, which supplies the high-side supply voltage, and the auxiliary input terminal, which supplies the auxiliary input voltage. The divider circuitry 310 is another example of the divider circuitry 136, 216 of FIGS. 1 and 2.

The transistor 312 has a first terminal, a second terminal, and a control terminal. The first terminal of the transistor 312 is coupled to the auxiliary input terminal, which supplies the auxiliary input voltage. The second terminal of the transistor 312 is coupled to the transistor 314. The control terminal of the transistor 312 is coupled to the buffer circuitry 302. The transistor 314 has a first terminal, a second terminal, and a control terminal. The first terminal of the transistor 314 is coupled to the transistor 312. The second terminal of the transistor 314 is coupled to the common terminal, which supplies the low-side supply voltage. The control terminal of the transistor 314 is coupled to the buffer circuitry 316. In the example of FIG. 3, the transistors 312, 314 are structured to supply a low-side input current (I_{INPUT_LOW}) to the common terminal. In the examples of FIGS. 1 and 2, the current mirror circuitry 160, 245 are structured to mirror the low-side input current. In such examples, the current mirror circuitry 160, 245 are coupled between the transistor 314 and the common potential.

The buffer circuitry 316 is coupled to the transistors 314, 320, 322, the current source circuitry 326, the common terminal, which supplies the low-side supply voltage, and the auxiliary input terminal, which supplies the auxiliary input voltage. The buffer circuitry 316 is another example of the buffer circuitry 144, 220 of FIGS. 1 and 2. The divider circuitry 318 is coupled to the buffer circuitry 316, the common terminal, which supplies the low-side supply voltage, and the auxiliary input terminal, which supplies the auxiliary input voltage. The divider circuitry 318 is another example of the divider circuitry 148, 222 of FIGS. 1 and 2.

The transistor 320 has a first terminal, a second terminal, and a control terminal. The first terminal of the transistor 320 is coupled to the buffer circuitry 308. The second terminal of the transistor 320 is coupled to the buffer circuitry 316. The control terminal of the transistor 320 is coupled to the auxiliary input terminal, which supplies the auxiliary input voltage. The transistor 322 has a first terminal, a second terminal, and a control terminal. The first terminal of the transistor 322 is coupled to the buffer circuitry 308. The second terminal of the transistor 322 is coupled to the buffer circuitry 316. The control terminal of the transistor 322 is coupled to the auxiliary input terminal, which supplies the auxiliary input voltage. In the example of FIG. 3, the transistors 320, 322 are structured to implement cascode control of currents between the buffer circuitry 308, 316. In such examples, coupling the control terminals of the transistors 320, 322 implements cascode control by selecting to form a current path between the buffer circuitry 308, 316 using one of the transistor 320 or the transistor 322.

The current source circuitry 324 has a first terminal and a second terminal. The first terminal of the current source circuitry 324 is coupled to the supply terminal, which supplies the high-side supply voltage. The second terminal of the current source circuitry 324 is coupled to the buffer circuitry 308. The current source circuitry 326 has a first terminal and a second terminal. The first terminal of the current source circuitry 326 is coupled to the buffer circuitry 316. The second terminal of the current source circuitry 326 is coupled to the common terminal, which supplies the low-side supply voltage. In the example of FIG. 3, the current source circuitry 324, 326 are structured as bias circuitry, which use bias currents to facilitate the buffer circuitry 308, 316 being in an operational state. For example, in response to the input voltage causing the auxiliary voltage to approach the high-side supply voltage, the current source circuitry 324, 326 supplies a current to drive the buffer circuitry 308, 316.

The buffer circuitry 328 is coupled to the divider circuitry 310, the transistors 320, 322, the current source circuitry 324, the resistor 330, the supply terminal, which supplies the high-side supply voltage, and the auxiliary input terminal, which supplies the auxiliary input voltage. The buffer circuitry 328 is an example of the buffer circuitry 224 of FIG. 2. The resistor 330 is coupled to the transistor 306, the buffer circuitry 328, and the capacitor 332. The resistor 330 is an example of the resistor 226 of FIG. 2. The capacitor 332 is coupled to the transistor 306, the resistor 330, and the supply terminal, which supplies the high-side supply voltage. The capacitor 332 is an example of the capacitor 228 of FIG. 2.

The transistor 334 has a first terminal, a second terminal, and a control terminal. The first terminal of the transistor 334 is coupled to the current source circuitry 324 and the transistor 338. The second terminal of the transistor 334 is coupled to the transistor 322. The control terminal of the transistor 334 is coupled to the divider circuitry 310 and the transistor 336. The transistor 336 has a first terminal, a second terminal, and a control terminal. The first terminal of the transistor 336 is coupled to the supply terminal, which supplies the high-side supply voltage. The second terminal of the transistor 336 is coupled to the transistors 320, 340. The control terminal of the transistor 336 is coupled to the divider circuitry 310 and the transistor 334.

The transistor 338 has a first terminal, a second terminal, and a control terminal. The first terminal of the transistor 338 is coupled to the supply terminal, which supplies the high-side supply voltage. The second terminal of the transistor 338 is coupled to the resistor 330 and the transistor 340. The control terminal of the transistor 338 is coupled to the current source circuitry 324 and the transistor 334. The transistor 340 has a first terminal, a second terminal, and a control terminal. The first terminal of the transistor 340 is coupled to the resistor 330 and the transistor 338. The second terminal of the transistor 340 is coupled to the auxiliary input terminal, which supplies the auxiliary input voltage. The control terminal of the transistor 340 is coupled to the transistors 320, 336. In the example of FIG. 3, the transistors 338, 340 are structured as emitter followers, which allows the transistors 338, 340 to generate voltages between the high-side supply voltage and the auxiliary voltage.

The resistor 342 is coupled to the buffer circuitry 308, the capacitors 344, 348, the resistor 346, and the supply terminal, which supplies the high-side supply voltage. The resistor 342 is an example of the resistor 230 of FIG. 2. The capacitor 344 has a first terminal and a second terminal. The first terminal of the capacitor 344 is coupled to the supply terminal, which supplies the high-side supply voltage. The second terminal of the capacitor 344 is coupled to the buffer circuitry 308, the resistors 342, 346, and the capacitor 348. The resistor 346 is coupled to the buffer circuitry 308, the resistor 342, the capacitors 344, 348, and the auxiliary input terminal, which supplies the auxiliary input voltage. The resistor 346 is an example of the resistor 232 of FIG. 2. The capacitor 348 has a first terminal and a second terminal. The first terminal of the capacitor 348 is coupled to the buffer circuitry 308, the resistors 342, 346, and the capacitor 344. The second terminal of the capacitor 348 is coupled to the auxiliary input terminal, which supplies the auxiliary input voltage.

In the example of FIG. 3, the resistors 342, 346 and the capacitors 344, 348 are structured as voltage divider circuitry, which divides the voltage between the high-side supply voltage and the auxiliary input voltage. Also, the resistors 342, 346 and the capacitors 344, 348 are structured as timing circuitry having a time constant that suppresses relatively high-frequency transients to improve stability at an input of the buffer circuitry 308.

The buffer circuitry 350 is coupled to the divider circuitry 318, the transistors 320, 322, the current source circuitry 326, the resistor 352, the common terminal, which supplies the low-side supply voltage, and the auxiliary input terminal, which supplies the auxiliary input voltage. The buffer circuitry 350 is an example of the buffer circuitry 234 of FIG. 2. The resistor 352 is coupled to the transistor 314, the buffer circuitry 350, and the capacitor 354. The resistor 352 is an example of the resistor 236 of FIG. 2. The capacitor 354 is coupled to the transistor 314, the resistor 352, and the common terminal, which supplies the low-side supply voltage. The capacitor 354 is an example of the capacitor 238 of FIG. 2.

The transistor 356 has a first terminal, a second terminal, and a control terminal. The first terminal of the transistor 356 is coupled to the transistors 322, 360. The second terminal of the transistor 356 is coupled to the common terminal, which supplies the low-side supply voltage. The control terminal of the transistor 356 is coupled to the divider circuitry 318 and the transistor 358. The transistor 358 has a first terminal, a second terminal, and a control terminal. The first terminal of the transistor 358 is coupled to the transistor 320. The second terminal of the transistor 358 is coupled to the current source circuitry 326 and the transistor 362. The control terminal of the transistor 358 is coupled to the divider circuitry 318 and the transistor 356.

The transistor 360 has a first terminal, a second terminal, and a control terminal. The first terminal of the transistor 360 is coupled to the auxiliary input terminal, which supplies the auxiliary input voltage. The second terminal of the transistor 360 is coupled to the resistor 352 and the transistor 362. The control terminal of the transistor 360 is coupled to the transistors 322, 356. The transistor 362 has a first terminal, a second terminal, and a control terminal. The first terminal of the transistor 362 is coupled to the resistor 352 and the transistor 360. The second terminal of the transistor 362 is coupled to the common terminal, which supplies the low-side supply voltage. The control terminal of the transistor 362 is coupled to the current source circuitry 326 and the transistor 358. In the example of FIG. 3, the transistors 360, 362 are structured as emitter followers, which allows the transistors 360, 362 to generate voltages between the auxiliary voltage and the low-side supply voltage.

The resistor 364 is coupled to the buffer circuitry 316, the capacitor 366, 370, the resistor 368, and the auxiliary input terminal, which supplies the auxiliary input voltage. The resistor 364 is an example of the resistor 240 of FIG. 2. The capacitor 366 has a first terminal and a second terminal. The first terminal of the capacitor 366 is coupled to the resistor 364 and the auxiliary input terminal, which supplies the auxiliary input voltage. The second terminal of the capacitor 366 is coupled to the buffer circuitry 316, the resistors 364, 368, and the capacitor 370. The resistor 368 is coupled to the buffer circuitry 316, the resistor 364, the capacitors 366, 370, and the common terminal, which supplies the low-side supply voltage. The capacitor 370 has a first terminal and a second terminal. The first terminal of the capacitor 370 is coupled to the buffer circuitry 316, the resistors 364, 368, and the capacitor 366. The second terminal of the capacitor 370 is coupled to the common terminal, which supplies the low-side supply voltage.

In the example of FIG. 3, the resistors 364, 368 and the capacitors 366, 370 are structured as voltage divider circuitry, which divides the voltage between the auxiliary input voltage and the low-side supply voltage. Also, the resistors 364, 368 and the capacitors 366, 370 are structured as timing circuitry having a time constant, which suppresses relatively high-frequency transients to improve stability at an input of the buffer circuitry 316.

In the example of FIG. 3, the transistors 304, 306, 320, 336, 338, 358, 360 are NPN BJTs. Alternatively, the transistors 304, 306, 320, 336, 338, 358, 360 may be n-channel FETs, n-channel IGBTs, n-channel JFETs, n-channel MOSFETs, or, with slight modifications, p-type equivalent devices. In the example of FIG. 3, the transistors 312, 314, 322, 334, 340, 356, 362 are PNP BJTs. Alternatively, the transistors 312, 314, 322, 334, 340, 356, 362 may be p-channel FETs, p-channel IGBTs, p-channel JFETs, p-channel MOSFETs, or, with slight modifications, N-type equivalent devices. The transistors 304, 306, 312, 314, 320, 322, 334, 336, 338,340, 356, 358, 360, 362 may be depletion mode devices, drain-extended devices, enhancement mode devices, natural transistors or other type of device structure transistors. Furthermore, the transistors 304, 306, 312, 314, 320, 322, 334, 336, 338,340, 356, 358, 360, 362 may be implemented in/over a silicon substrate (Si), a silicon carbide substrate (SiC), a gallium nitride substrate (GaN) or a gallium arsenide substrate (GaAs).

FIGS. 4A and 4B are a schematic diagram of example output stage circuitry 400, which is an example implementation of the output stage circuitry 120, 208 of FIGS. 1 and 2. In the example of FIGS. 4A and 4B, the output stage circuitry 400 includes first current mirror circuitry 402, a first transistor 403, second current mirror circuitry 404, a second transistor 405, pre-driver circuitry 406, a third transistor 407, a fourth transistor 408, a fifth transistor 409, a sixth transistor 410, third current mirror circuitry 412, a seventh transistor 413, first bootstrap buffer circuitry 414, first current source circuitry 415, fourth current mirror circuitry 416, first divider circuitry 418, an eighth transistor 419, a ninth transistor 420, a tenth transistor 421, an eleventh transistor 422, fifth current mirror circuitry 424, a twelfth transistor 425, second bootstrap buffer circuitry 426, second current source circuitry 427, sixth current mirror circuitry 428, second divider circuitry 430, a thirteenth transistor 431, a first resistor 432, a second resistor 433, a fourteenth transistor 434, a third resistor 435, a fifteenth transistor 436, a fourth resistor 437, first buffer circuitry 438, a fifth resistor 439, a sixteenth transistor 440, a sixth resistor 441, a seventeenth transistor 442, an eighteenth transistor 443, a nineteenth transistor 444, and a twentieth transistor 445.

The example pre-driver circuitry 406 of FIG. 4A includes a first example transistor 446, a second example transistor 447, a third example transistor 448, a fourth example transistor 449, a fifth example transistor 450, a sixth example transistor 451, a seventh example transistor 452, a first example capacitor 453, an eighth example transistor 454, a ninth example transistor 455, a tenth example transistor 456, a second example capacitor 457, an eleventh example transistor 458, a twelfth example transistor 459, a thirteenth example transistor 460, a first example resistor 461, a second example resistor 462, and a fourteenth example transistor 463. The example buffer circuitry 414 of FIG. 4B includes example buffer circuitry 464, a first example resistor 465, a second example resistor 466, and an example capacitor 467. The example divider circuitry 418 of FIG. 4B includes a first example resistor 468 and a second example resistor 469. The example buffer circuitry 426 of FIG. 4B includes example buffer circuitry 472, a first example resistor 473, a second example resistor 474, and an example capacitor 475. The example divider circuitry 430 of FIG. 4B includes a first example resistor 476 and a second example resistor 478.

The current mirror circuitry 402 is coupled to the input stage circuitry 116, 206, 300 of FIGS. 1, 2, and 3, the transistors 403, 407, 408, the current mirror circuitry 412, and the supply terminal, which supplies the high-side supply voltage. The current mirror circuitry 402 is another example of the current mirror circuitry 152, 243 of FIGS. 1 and 2. The transistor 403 is coupled to the current mirror circuitry 402, the pre-driver circuitry 406, the transistors 407, 410, 413, and the buffer circuitry 414. The transistor 403 is another example of the transistors 156, 244 of FIGS. 1 and 2. The current mirror circuitry 404 is coupled to the input stage circuitry 116, 206, the transistors 405, 419, 420, the current mirror circuitry 424, and the common terminal, which supplies the low-side supply voltage. The transistor 405 is coupled to the current mirror circuitry 404, the pre-driver circuitry 406, the transistors 419, 420, 422, 425, and the buffer circuitry 426. The transistor 405 is another example of the transistors 164, 246 of FIGS. 1 and 2.

The pre-driver circuitry 406 is coupled to the transistors 403, 405, 407, 408, 409, 410, 419, 420, 421, 422, 431, 434, and an output terminal, which supplies an output voltage to a load. The pre-driver circuitry 406 is another example of the pre-driver circuitry 168, 248 of FIGS. 1 and 2. In the example of FIG. 4, the pre-driver circuitry 406 is structured as a three-rank pre-driver, which uses three sets of transistors to produce a relatively high output current, relatively low quiescent current, and relatively high linearity.

The transistor 407 has a first terminal, a second terminal, and a control terminal. The first terminal of the transistor 407 is coupled to the current mirror circuitry 402. The second terminal of the transistor 407 is coupled to the pre-driver circuitry 406. The control terminal of the transistor 407 is coupled to the transistors 403, 410, 413 and the buffer circuitry 414. The transistor 408 is coupled to the current mirror circuitry 402, 412, the pre-driver circuitry 406, the transistor 409, and the buffer circuitry 414. The transistor 408 is another example of the transistors 170, 249 of FIGS. 1 and 2. The transistor 409 is coupled to the pre-driver circuitry 406, the transistor 408, the buffer circuitry 414, and the supply terminal, which supplies the high-side supply voltage. The transistor 409 is another example of the transistors 172, 250 of FIGS. 1 and 2.

The transistor 410 has a first terminal, a second terminal, and a control terminal. The first terminal of the transistor 410 is coupled to the current mirror circuitry 412. The second terminal of the transistor 410 is coupled to the pre-driver circuitry 406. The control terminal of the transistor 410 is coupled to the transistors 403, 407, 413 and the buffer circuitry 414.

The current mirror circuitry 412 has a first terminal, a second terminal, a third terminal, a fourth terminal, and a fifth terminal. The first terminal of the current mirror circuitry 412 is coupled to the supply terminal, which supplies the high-side supply voltage. The second terminal of the current mirror circuitry 412 is coupled to the current mirror circuitry 402 and the transistor 408. The third terminal of the current mirror circuitry 412 is coupled to the transistor 410. The fourth terminal of the current mirror circuitry 412 is coupled to the buffer circuitry 414 and the current mirror circuitry 416. The fifth terminal of the current mirror circuitry 412 is coupled to the buffer circuitry 426. In the example of FIGS. 4A and 4B, the current mirror circuitry 412 is structured as feedback circuitry, which biases the output stage circuitry 400 using a feedback current (I_{OUT/256}) and a dynamic bias current (IB_{dynamic}) that are proportional to an output current at the output terminal. Advantageously, the current mirror circuitry 412 dynamically boosts the output stage circuitry 400 using feedback currents. Advantageously, the current mirror circuitry 412 decreases the response time of the output voltage by dynamically adjusting currents at the output of the output stage circuitry 400.

The transistor 413 has a first terminal, a second terminal, and a control terminal. The first terminal of the transistor 413 is coupled to the supply terminal, which supplies the high-side supply voltage. The second terminal of the transistor 413 is coupled to the transistor 431. The control terminal of the transistor 413 is coupled to the transistors 403, 407, 410 and the buffer circuitry 414.

The buffer circuitry 414 is coupled to the transistors 403, 407, 408, 409, 410, 413, 442, 443, the current mirror circuitry 412, 424, the divider circuitry 418, the supply terminal, which supplies the high-side supply voltage, and an auxiliary output terminal, which supplies an auxiliary output voltage (auxiliary VOUT). The auxiliary output voltage is proportional to the output voltage at the output terminal of the pre-driver circuitry 406. The buffer circuitry 414 is another example of the buffer circuitry 176, 252 of FIGS. 1 and 2.

The current source circuitry 415 has a first terminal and a second terminal. The first terminal is coupled to the current mirror circuitry 416. The second terminal of the current source circuitry 415 is coupled to the common terminal, which supplies the common potential. The current mirror circuitry 416 has a first terminal, a second terminal, and a third terminal. The first terminal of the current mirror circuitry 416 is coupled to the supply terminal, which supplies the low-side supply voltage. The second terminal of the current mirror circuitry 416 is coupled to the current source circuitry 415. The third terminal of the current mirror circuitry 416 is coupled to the buffer circuitry 414. In the example of FIG. 4, the current source circuitry 415 and the current mirror circuitry 416 are structured as bias circuitry, which supplies a bias current to facilitate the buffer circuitry 414 being in an operational state. Alternatively, the output stage circuitry 400 may be modified to replace the current source circuitry 415 and the current mirror circuitry 416 with current source circuitry structured as bias current source circuitry (e.g., the current source circuitry 324 of FIG. 3).

The divider circuitry 418 is coupled to the buffer circuitry 414, the transistors 442, 443, the supply terminal, which supplies the high-side supply voltage, and the auxiliary output terminal, which supplies the auxiliary output voltage. The divider circuitry 418 is another example of the divider circuitry 180, 253 of FIGS. 1 and 2.

The transistor 419 has a first terminal, a second terminal, and a control terminal. The first terminal of the transistor 419 is coupled to the pre-driver circuitry 406. The second terminal of the transistor 419 is coupled to the current mirror circuitry 404. The control terminal of the transistor 419 is coupled to the transistors 405, 422, 425 and the buffer circuitry 426. The transistor 420 is coupled to the current mirror circuitry 404, 424, the pre-driver circuitry 406, the transistor 421, and the buffer circuitry 426. The transistor 420 is another example of the transistors 182, 254 of FIGS. 1 and 2. The transistor 421 is coupled to the pre-driver circuitry 406, the transistor 420, the buffer circuitry 426, and the common terminal, which supplies the low-side supply voltage. The transistor 421 is another example of the transistors 184, 255 of FIGS. 1 and 2. The transistor 422 has a first terminal, a second terminal, and a control terminal. The first terminal of the transistor 422 is coupled to pre-driver circuitry 406. The second terminal of the transistor 422 is coupled to the current mirror circuitry 424. The control terminal of the transistor 422 is coupled to the transistors 405, 419, 425 and the buffer circuitry 426.

The current mirror circuitry 424 has a first terminal, a second terminal, a third terminal, a fourth terminal, and a fifth terminal. The first terminal of the current mirror circuitry 424 is coupled to the common terminal, which supplies the low-side supply voltage. The second terminal of the current mirror circuitry 424 is coupled to the current mirror circuitry 404 and the transistor 420. The third terminal of the current mirror circuitry 424 is coupled to the transistor 422. The fourth terminal of the current mirror circuitry 424 is coupled to the buffer circuitry 414. The fifth terminal of the current mirror circuitry 424 is coupled to the buffer circuitry 426 and the current mirror circuitry 428. In the example of FIG. 4, the current mirror circuitry 428 is structured as feedback circuitry, which biases the output stage circuitry 400 using a feedback current (I_{OUT/256}) and a dynamic bias current (IB_{dynamic}) that are proportional to the output current at the output terminal. Advantageously, the current mirror circuitry 428 decreases a response time of the output voltage by dynamically biasing the output stage circuitry 400.

The transistor 425 has a first terminal, a second terminal, and a control terminal. The first terminal of the transistor 425 is coupled to the transistor 434. The second terminal of the transistor 425 is coupled to the common terminal, which supplies the low-side supply voltage. The control terminal of the transistor 425 is coupled to the transistors 405, 419, 422 and the buffer circuitry 426.

The buffer circuitry 426 is coupled to the transistors 405, 419, 420, 421, 422, 425, 444, 445, the current mirror circuitry 412, 424, the divider circuitry 430, the common terminal, which supplies the low-side supply voltage, and the auxiliary output terminal, which supplies the auxiliary output voltage. The buffer circuitry 426 is another example of the buffer circuitry 188, 257 of FIGS. 1 and 2.

The current source circuitry 427 has a first terminal and a second terminal. The first terminal of the current source circuitry 427 is coupled to the supply terminal, which supplies a supply voltage. The second terminal of the current source circuitry 427 is coupled to the current mirror circuitry 428. The current mirror circuitry 428 has a first terminal, a second terminal, and a third terminal. The first terminal of the current mirror circuitry 428 is coupled to the common terminal, which supplies the low-side supply voltage. The second terminal of the current mirror circuitry 428 is coupled to the current source circuitry 427. The third terminal of the current mirror circuitry 428 is coupled to the current mirror circuitry 424 and the buffer circuitry 426. In the example of FIG. 4, the current source circuitry 427 and the current mirror circuitry 428 are structured as bias circuitry, which sinks a bias current to facilitate the buffer circuitry 426 being in an operational state. Alternatively, the output stage circuitry 400 may be modified to replace the current source circuitry 427 and the current mirror circuitry 428 with current source circuitry structured as bias current source circuitry (e.g., the current source circuitry 326 of FIG. 3).

The divider circuitry 430 is coupled to the buffer circuitry 426, the transistors 444, 445, the common terminal, which supplies the low-side supply voltage, and the auxiliary output terminal, which supplies the auxiliary output voltage. The divider circuitry 430 is another example of the divider circuitry 192, 258 of FIGS. 1 and 2.

The transistor 431 has a first terminal, a second terminal, and a control terminal. The first terminal of the transistor 431 is coupled to the transistor 413. The second terminal of the transistor 431 is coupled to the resistor 432. The control terminal of the transistor 431 is coupled to the pre-driver circuitry 406. The resistor 432 has a first terminal and a second terminal. The first terminal of the resistor 432 is coupled to the transistor 431. The second terminal of the resistor 432 is coupled to the auxiliary output terminal.

The resistor 433 has a first terminal and a second terminal. The first terminal of the resistor 433 is coupled to the auxiliary output terminal. The second terminal of the resistor 433 is coupled to the transistor 434. The transistor 434 has a first terminal, a second terminal, and a control terminal. The first terminal of the transistor 434 is coupled to the resistor 433. The second terminal of the transistor 434 is coupled to the transistor 425. The control terminal of the transistor 434 is coupled to the pre-driver circuitry 406. In the example of FIGS. 4A and 4B, the transistors 413, 425, 431, 434 and the resistors 432, 433 are structured to set the auxiliary output voltage proportional to the output voltage at the output terminal.

The resistor 435 has a first terminal and a second terminal. The first terminal of the resistor 435 is coupled to the supply terminal, which supplies the high-side supply voltage. The second terminal of the resistor 435 is coupled to the transistor 436 and the resistor 437. The transistor 436 has a first terminal, a second terminal, and a control terminal. The first terminal of the transistor 436 is coupled to the supply terminal, which supplies the high-side supply voltage. The second terminal of the transistor 436 is coupled to the buffer circuitry 438. The control terminal of the transistor 436 is coupled to the resistors 435, 437. The resistor 437 has a first terminal and a second terminal. The first terminal of the resistor 437 is coupled to the resistor 435 and the transistor 436. The second terminal of the resistor 437 is coupled to the buffer circuitry 438 and the resistor 439.

The buffer circuitry 438 has a first terminal, a second terminal, a third terminal, and a fourth terminal. The first terminal of the buffer circuitry 438 is coupled to the transistor 436. The second terminal of the buffer circuitry 438 is coupled to the resistors 437, 439. The third terminal of the buffer circuitry 438 is coupled to the transistor 440. The fourth terminal of the buffer circuitry 438 is coupled to the transistors 443, 444.

The resistor 439 has a first terminal and a second terminal. The first terminal of the resistor 439 is coupled to the resistor 437 and the buffer circuitry 438. The second terminal of the resistor 439 is coupled to the transistor 440 and the resistor 441. The transistor 440 has a first terminal, a second terminal, and a control terminal. The first terminal of the transistor 440 is coupled to the buffer circuitry 438. The second terminal of the transistor 440 is coupled to the common terminal, which supplies the low-side supply voltage. The control terminal of the transistor 440 is coupled to the resistors 439, 441. The resistor 441 has a first terminal and a second terminal. The first terminal of the resistor 441 is coupled to the resistor 439 and the transistor 440. The second terminal of the resistor 441 is coupled to the common terminal, which supplies the low-side supply voltage.

The transistor 442 has a first terminal, a second terminal, and a control terminal. The first terminal of the transistor 442 is coupled to the supply terminal, which supplies the high-side supply voltage. The second terminal of the transistor 442 is coupled to the buffer circuitry 414, the divider circuitry 418, and the transistor 443. The transistor 443 has a first terminal, a second terminal, and a control terminal. The first terminal of the transistor 443 is coupled to the buffer circuitry 414, the divider circuitry 418, and the transistor 442. The second terminal of the transistor 443 is coupled to the buffer circuitry 438 and the transistor 444. The control terminals of the transistors 442, 443 are coupled to the buffer circuitry 414.

The transistor 444 has a first terminal, a second terminal, and a control terminal. The first terminal of the transistor 444 is coupled to the buffer circuitry 438 and the transistor 443. The second terminal of the transistor 444 is coupled to the buffer circuitry 426, the divider circuitry 430, and the transistor 445. The transistor 445 has a first terminal, a second terminal, and a control terminal. The first terminal of the transistor 445 is coupled to the buffer circuitry 426, the divider circuitry 430, and the transistor 444. The second terminal of the transistor 444 is coupled to the common terminal, which supplies the low-side supply voltage. The control terminals of the transistors 444, 445 are coupled to the buffer circuitry 426.

In the example of FIG. 4, the resistors 435, 437, 439, 441 are structured as voltage divider circuitry, which divides the voltage difference between the high-side supply voltage and the low-side supply voltage. The resistors 435, 437, 439, 441 are structured to generate operating points that control the transistors 436, 440 in relation to the high-side supply voltage and the low-side supply voltage. The transistors 436, 440 are structured to adjust the output currents of the buffer circuitry 438. Such an adjustment may be referred to as regulating a common mode voltage. In the example of FIG. 4, the transistors 442, 443, 444, 445 are structured to set a common mode voltage of the buffer circuitry 414, 426 based on the buffer circuitry 438.

The transistor 446 has a first terminal, a second terminal, and a control terminal. The first terminal of the transistor 446 is coupled to the transistors 403, 448 and the capacitor 453. The transistor 447 has a first terminal, a second terminal, and a control terminal. The second terminal of the transistor 446, the first terminal of the transistor 447, and the control terminals of the transistors 446, 447 are coupled together. The second terminal of the transistor 447 is coupled to the transistors 405, 449 and the capacitor 457.

The transistor 448 has a first terminal, a second terminal, and a control terminal. The first terminal of the transistor 448 is coupled to the transistor 407. The second terminal of the transistor 448 is coupled to the transistors 454, 455. The control terminal of the transistor 448 is coupled to the transistors 403, 446 and the capacitor 453. The transistor 449 has a first terminal, a second terminal, and a control terminal. The first terminal of the transistor 449 is coupled to the transistors 450, 451. The second terminal of the transistor 449 is coupled to the transistor 419. The control terminal of the transistor 449 is coupled to the transistors 405, 447 and the capacitor 457.

The transistor 450 has a first terminal, a second terminal, and a control terminal. The first terminal of the transistor 450 is coupled to the transistors 408, 451, 452. The second terminal of the transistor 450 is coupled to the transistors 449, 451. The control terminal of the transistor 450 is coupled to the transistor 451. The transistor 451 has a first terminal, a second terminal, and a control terminal. The first terminal of the transistor 451 is coupled to the transistors 408, 450, 452. The second terminal of the transistor 451 is coupled to the transistors 449, 450. The control terminal of the transistor 451 is coupled to the transistor 450. The transistor 452 has a first terminal, a second terminal, and a control terminal. The first terminal of the transistor 452 is coupled to the transistor 409. The second terminal of the transistor 452 is coupled to the capacitor 453 and the transistors 431, 458, 459, 460. The capacitor 453 has a first terminal and a second terminal. The first terminal of the capacitor 453 is coupled to the transistors 403, 446, 448. The second terminal of the capacitor 453 is coupled to the transistors 431, 452, 458, 459, 460.

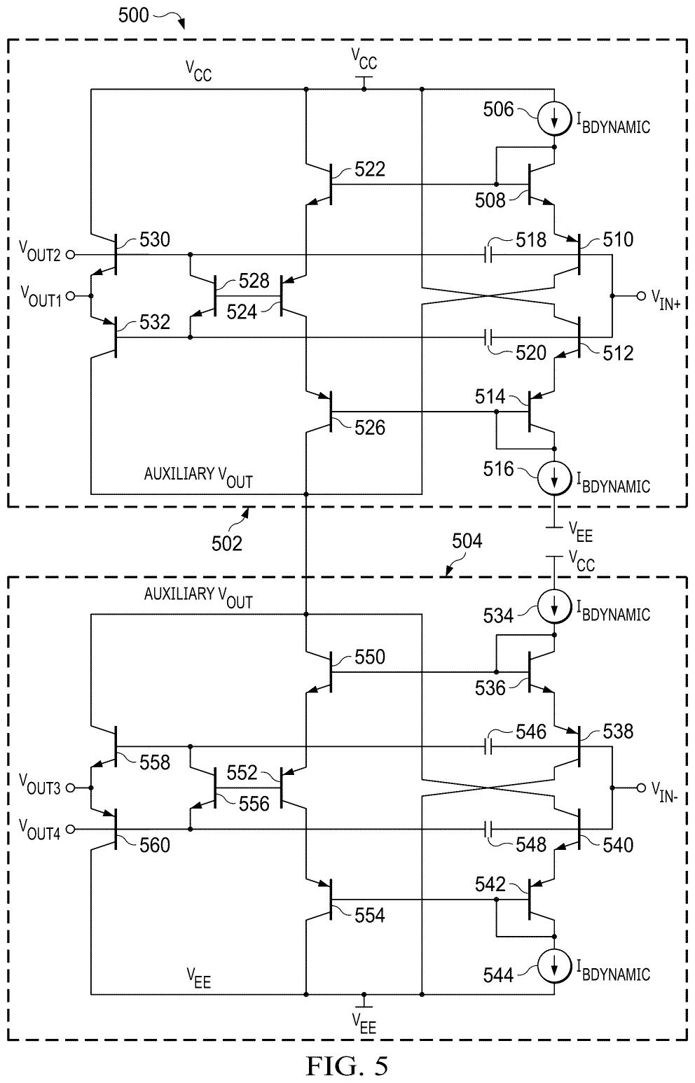

The transistor 454 has a first terminal, a second terminal, and a third terminal. The first terminal of the transistor 454 is coupled to the transistors 448, 455. The second terminal of the transistor 454 is coupled to the transistors 420, 455, 456. The control terminal of the transistor 454 is coupled to the transistor 455. The transistor 455 has a first terminal, a second terminal, and a control terminal. The first terminal of the transistor 455 is coupled to the transistors 448, 454. The second terminal of the transistor 455 is coupled to the transistors 420, 454, 456. The control terminal of the transistor 455 is coupled to the transistor 454. The transistor 456 has a first terminal, a second terminal, and a control terminal. The first terminal of the transistor 456 is coupled to the transistors 434, 458, 459, 463 and the capacitor 457. The second terminal of the transistor 456 is coupled to the transistor 421. The control terminal of the transistor 456 is coupled to the transistors 420, 454, 455. The capacitor 457 has a first terminal and a second terminal. The first terminal of the capacitor 457 is coupled to the transistors 405, 447, 449. The second terminal of the capacitor 457 is coupled to the transistors 434, 456, 458, 459, 463. In the example of FIG. 5, the capacitors 453, 457 are structured as capacitor circuitry, which generates a reference voltage responsive to currents. In some examples, the pre-driver circuitry 406 may be modified such that the capacitors 453, 457 form capacitor circuitry that is external to the pre-driver circuitry 406, such as in FIGS. 2 and 6.

The transistor 458 has a first terminal, a second terminal, and a control terminal. The first terminal of the transistor 458 is coupled to the transistors 431, 452, 459, 460 and the capacitor 453. The second terminal of the transistor 458 is coupled to the transistors 434, 456, 459, 463 and the capacitor 457. The control terminal of the transistor 458 is coupled to the transistor 459. The transistor 459 has a first terminal, a second terminal, and a control terminal. The first terminal of the transistor 459 is coupled to the transistors 431, 452, 458, 460 and the capacitor 453. The second terminal of the transistor 459 is coupled to the transistors 434, 456, 458, 463 and the capacitor 457. The control terminal of the transistor 459 is coupled to the transistor 458.

The transistor 460 has a first terminal, a second terminal, and a control terminal. The first terminal of the transistor 460 is coupled to the transistor 410. The second terminal of the transistor 460 is coupled to the resistor 461. The control terminal of the transistor 460 is coupled to the transistors 431, 452, 458, 459 and the capacitor 453. The resistor 461 has a first terminal and a second terminal. The first terminal of the resistor 461 is coupled to the transistor 431. The second terminal of the resistor 461 is coupled to the resistor 433 and the output terminal, which may be coupled to a load.

The resistor 462 has a first terminal and a second terminal. The first terminal of the resistor 462 is coupled to the resistor 432 and the output terminal. The second terminal of the resistor 462 is coupled to the transistor 434. The transistor 463 has a first terminal, a second terminal, and a control terminal. The first terminal of the transistor 463 is coupled to the resistor 433. The second terminal of the transistor 463 is coupled to the transistor 422. The control terminal of the transistor 463 is coupled to the transistor 434, 456, 458, 459 and the capacitor 457.

In the example of FIGS. 4A and 4B, the transistors 410, 422, 460, 463 and the resistors 461, 462 are structured to set the output voltage at the output terminal. In the example of FIG. 4A, the transistors 460, 463 and the resistors 461, 462 are structured as emitter followers, which allows the transistors 460, 463 to generate voltages between the high-side supply voltage and the low-side supply voltage. Advantageously, the pre-driver circuitry 406 supports output voltages between the high-side supply voltage and the low-side supply voltage.

The buffer circuitry 464 is coupled to the current mirror circuitry 412, 416, 424, the divider circuitry 418, the transistors 442, 443, the resistors 465, 466, the supply terminal, which supplies the high-side supply voltage, and the auxiliary output terminal, which supplies the auxiliary output voltage. The buffer circuitry 464 is another example of the buffer circuitry 266 of FIG. 2. The resistor 465 is coupled to the transistors 403, 407, 410, 413, 442, 443, the buffer circuitry 464, and the capacitor 467. The resistor 465 is an example of the resistor 267 of FIG. 2. The resistor 466 is coupled to the transistors 408, 409 and the buffer circuitry 464. The resistor 466 is an example of the resistor 268 of FIG. 2. The capacitor 467 is coupled to the transistors 403, 407, 410, the resistor 465, and the supply terminal, which supplies the high-side supply voltage. The capacitor 467 is an example of the capacitor 269 of FIG. 2.

The resistor 468 is coupled to the buffer circuitry 414, the resistor 469, and the supply terminal, which supplies the high-side supply voltage. The resistor 468 is an example of the resistor 270 of FIG. 2. The resistor 469 is coupled to the buffer circuitry 414, the resistor 468, and the auxiliary output terminal, which supplies the auxiliary output voltage. The resistor 469 is an example of the resistor 271 of FIG. 2.

The buffer circuitry 472 is coupled to the current mirror circuitry 412, 424, 428, the transistors 444, 445, the resistor 473, the common terminal, which supplies the low-side supply voltage, and the auxiliary output terminal, which supplies the auxiliary output voltage. The buffer circuitry 472 is an example of the buffer circuitry 272 of FIG. 2. The resistor 473 is coupled to the transistors 405, 419, 422, 425, 444, 445, the buffer circuitry 472, and the capacitor 475. The resistor 473 is an example of the resistor 274 of FIG. 2. The resistor 474 is coupled to the transistors 420, 421 and the buffer circuitry 472. The resistor 474 is an example of the resistor 273 of FIG. 2. The capacitor 475 is coupled to the transistors 405, 419, 425, the resistor 473, and the common terminal, which supplies the low-side supply voltage. The capacitor 475 is an example of the capacitor 275 of FIG. 2.

The resistor 476 is coupled to the buffer circuitry 426, the resistor 478, and the auxiliary output terminal, which supplies the auxiliary output voltage. The resistor 476 is an example of the resistor 276 of FIG. 2. The resistor 478 is coupled to the buffer circuitry 426, the resistor 476, and the common terminal, which supplies the low-side supply voltage. The resistor 478 is an example of the resistor 277 of FIG. 2.

In the example of FIGS. 4A and 4B, the transistors 405, 407, 409, 410, 413, 420, 431, 436, 442, 444, 447, 448, 450, 452, 454, 458, 460 are NPN BJTs. Alternatively, the transistors 405, 407, 409, 410, 413, 420, 431, 436, 442, 444, 447, 448, 450, 452, 454, 458, 460 may be n-channel FETs, n-channel IGBTs, n-channel JFETs, n-channel MOSFETs, or, with slight modifications, p-type equivalent devices. In the example of FIGS. 4A and 4B, the transistors 403, 408, 419, 421, 422, 425, 434, 440, 443, 445, 446, 449, 451, 454, 456, 459, 463 are PNP BJTs. Alternatively, the transistors 403, 408, 419, 421, 422, 425, 434, 440, 443, 445, 446, 449, 451, 454, 456, 459, 463 may be p-channel FETs, p-channel IGBTs, p-channel JFETs, p-channel MOSFETs, or, with slight modifications, N-type equivalent devices. The transistors 403, 405, 407, 408, 409, 410, 413, 419, 420, 421, 422, 425, 431, 434, 436, 440, 442, 443, 444, 445, 446, 447, 448, 449, 450, 451, 452, 454, 456, 458, 459, 460, 463 may be depletion mode devices, drain-extended devices, enhancement mode devices, natural transistors or other type of device structure transistors. Furthermore, the transistors 403, 405, 407, 408, 409, 410, 413, 419, 420, 421, 422, 425, 431, 434, 436, 440, 442, 443, 444, 445, 446, 447, 448, 449, 450, 451, 452, 454, 456, 458, 459, 460, 463 may be implemented in/over a silicon substrate (Si), a silicon carbide substrate (SiC), a gallium nitride substrate (GaN) or a gallium arsenide substrate (GaAs).

FIG. 5 is a schematic diagram of example buffer circuitry 500, which is an example implementation of the buffer circuitry 266, 272, 464, 472 of FIGS. 2 and 4B. In the example of FIG. 5, the buffer circuitry 500 includes first example buffer circuitry 502 and second example buffer circuitry 504. The example buffer circuitry 502 of FIG. 5, which is an example of the buffer circuitry 266, 464, includes first example current source circuitry 506, a first example transistor 508, a second example transistor 510, a third example transistor 512, a fourth example transistor 514, second example current source circuitry 516, a first example capacitor 518, a second example capacitor 520, a fifth example transistor 522, a sixth example transistor 524, a seventh example transistor 526, an eighth example transistor 528, a ninth example transistor 530, and a tenth example transistor 532. The example buffer circuitry 504 of FIG. 5, which is an example of the buffer circuitry 272, 472, includes first example current source circuitry 534, a first example transistor 536, a second example transistor 538, a third example transistor 540, a fourth example transistor 542, second example current source circuitry 544, a first example capacitor 546, a second example capacitor 548, a fifth example transistor 550, a sixth example transistor 552, a seventh example transistor 554, an eighth example transistor 556, a ninth example transistor 558, and a tenth example transistor 560.

The buffer circuitry 502 has a first terminal, a second terminal, an input terminal, a first output terminal, and a second output terminal. The first terminal of the buffer circuitry 502 is coupled to the supply terminal, which supplies the high-side supply voltage. The second terminal of the buffer circuitry 502 is coupled to the auxiliary output terminal, which supplies the auxiliary output voltage. The input terminal of the buffer circuitry 502 is structured to be coupled to the divider circuitry 180, 253, 418 of FIGS. 1, 2, and 4B, which supplies a high-side operating voltage (V_{IN+}). The first output terminal of the buffer circuitry 502 is structured to be coupled to the transistors 170, 172, 249, 250, 408, 409 of FIGS. 1, 2, and 4A. The second output terminal of the buffer circuitry 502 is structured to be coupled to the transistors 156, 244, 251, 403, 407, 410, 413 of FIGS. 1, 2, 4A, and 4B. The buffer circuitry 502 is structured as a buffer, which generates a first output voltage (V_{OUT1}) and a second output voltage (V_{OUT2}) by buffering the high-side operating voltage at the input terminal. The first output voltage is approximately equal to the high-side operating voltage at the input terminal of the buffer circuitry 502. The second output voltage is approximately one base-emitter voltage (V_{BE}) greater than the high-side operating voltage at the input terminal of the buffer circuitry 502.

The buffer circuitry 504 has a first terminal, a second terminal, an input terminal, a first output terminal, and a second output terminal. The first terminal of the buffer circuitry 504 is coupled to the common terminal, which supplies the low-side supply voltage. The second terminal of the buffer circuitry 504 is coupled to the auxiliary output terminal, which supplies the auxiliary output voltage. The input terminal of the buffer circuitry 504 is structured to be coupled to the divider circuitry 192, 258, 430 of FIGS. 1, 2, and 4B, which supplies a low-side operating voltage (V_{IN-}). The first output terminal of the buffer circuitry 504 is structured to be coupled to the transistors 164, 246, 256, 405, 419, 422, 425 of FIGS. 1, 2, 4A, and 4B. The second output terminal of the buffer circuitry 504 is structured to be coupled to the transistors 182, 184, 254, 255, 420, 421 of FIGS. 1, 2, and 4A. The buffer circuitry 504 is structured as a buffer, which generates a third output voltage (V_{OUT3}) and a fourth output voltage (V_{OUT4}) by buffering the low-side operating voltage at the input terminal. The third output voltage is approximately equal to the low-side operating voltage at the input terminal of the buffer circuitry 504. The fourth output voltage is approximately one base-emitter voltage (V_{BE}) less than the low-side operating voltage at the input terminal of the buffer circuitry 504.

The current source circuitry 506 has a first terminal and a second terminal. The first terminal of the current source circuitry 506 is coupled to the supply terminal, which supplies the high-side supply voltage. The second terminal of the current source circuitry 506 is coupled to the transistors 508, 522. In the example of FIG. 5, the current source circuitry 506 is structured to represent the bias currents from the current mirror circuitry 412, 416 of FIGS. 4A and 4B. Also, the current source circuitry 506 is structured as bias circuitry, which uses a bias current to facilitate the buffer circuitry 502 being in an operational state. Alternatively, as shown in FIGS. 4A and 4B, the current source circuitry 506 may be external to the buffer circuitry 502.

The transistor 508 has a first terminal, a second terminal, and a control terminal. The first and control terminals of the transistor 508 are coupled to the current source circuitry 506 and the transistor 522. The second terminal of the transistor 508 is coupled to the transistor 510. The transistor 510 has a first terminal, a second terminal, and a control terminal. The first terminal of the transistor 510 is coupled to the transistor 508. The second terminal of the transistor 510 is coupled to the auxiliary output terminal, which supplies the auxiliary output voltage. The control terminal of the transistor 510 is coupled to the input terminal of the buffer circuitry 502, the transistor 512, and the capacitors 518, 520.

The transistor 512 has a first terminal, a second terminal, and a control terminal. The first terminal of the transistor 512 is coupled to the supply terminal, which supplies the high-side supply voltage. The second terminal of the transistor 512 is coupled to the transistor 514. The control terminal of the transistor 512 is coupled to the input terminal of the buffer circuitry 502, the transistor 510, and the capacitors 518, 520. The transistor 514 has a first terminal, a second terminal, and a control terminal. The first terminal of the transistor 514 is coupled to the transistor 512. The second and control terminals of the transistor 514 are coupled to the current source circuitry 516 and the transistor 526.

The current source circuitry 516 has a first terminal and a second terminal. The first terminal of the current source circuitry 516 is coupled to the transistors 514, 526. The second terminal of the current source circuitry 516 is coupled to the common terminal, which supplies the common emitter voltage. In the example of FIG. 5, the current source circuitry 516 is structured to represent the bias currents from the current mirror circuitry 424, 428 of FIGS. 4A and 4B. Also, the current source circuitry 516 is structured as bias circuitry, which uses a bias current to facilitate the buffer circuitry 502 being in an operational state. Alternatively, as shown in FIGS. 4A and 4B, the current source circuitry 516 may be external to the buffer circuitry 502.

The capacitor 518 has a first terminal and a second terminal. The first terminal of the capacitor 518 is coupled to the input terminal of the buffer circuitry 502, the transistors 510, 512, and the capacitor 520. The second terminal of the capacitor 518 is coupled to the transistors 528, 530 and the first output terminal of the buffer circuitry 502. The capacitor 520 has a first terminal and a second terminal. The first terminal of the capacitor 520 is coupled to the input terminal of the buffer circuitry 502, the transistors 510, 512, and the capacitor 518. The second terminal of the capacitor 520 is coupled to the transistors 528, 532.

The transistor 522 has a first terminal, a second terminal, and a control terminal. The first terminal of the transistor 522 is coupled to the supply terminal, which supplies the high-side supply voltage. The second terminal of the transistor 522 is coupled to the transistor 524. The control terminal of the transistor 522 is coupled to the current source circuitry 506 and the transistor 508. In the example of FIG. 5, the transistors 508, 522 form current mirror circuitry, which is structured to have the transistor 522 mirror the current flowing through the transistor 508. In other examples, the current mirror circuitry 243, 245 of FIG. 2 may be implemented using a plurality of transistors, similar to the structure of the transistors 508, 522.

The transistor 524 has a first terminal, a second terminal, and a control terminal. The first terminal of the transistor 524 is coupled to the transistor 522. The second terminal of the transistor 524 is coupled to the transistor 526. The control terminal of the transistor 524 is coupled to the transistor 528. The transistor 526 has a first terminal, a second terminal, and a control terminal. The first terminal of the transistor 526 is coupled to the transistor 524. The second terminal of the transistor 526 is coupled to the auxiliary output terminal, which supplies the auxiliary output voltage. The control terminal of the transistor 526 is coupled to the transistor 514 and the current source circuitry 516. The transistor 528 has a first terminal, a second terminal, and a control terminal. The first terminal of the transistor 528 has a first terminal coupled to the capacitor 518, the transistor 530, and the first output terminal of the buffer circuitry 502. The second terminal of the transistor 528 is coupled to the capacitor 520 and the transistor 532. The control terminal of the transistor 528 is coupled to transistor 524.

The transistor 530 has a first terminal, a second terminal, and a control terminal. The first terminal of the transistor 530 is coupled to the supply terminal, which supplies the high-side supply voltage. The second terminal of the transistor 530 is coupled to the transistor 532 and the second output terminal of the buffer circuitry 502. The control terminal of the transistor 530 is coupled to the capacitor 518, the transistor 528, and the second output terminal of the buffer circuitry 502. The transistor 532 has a first terminal, a second terminal, and a control terminal. The first terminal of the transistor 532 is coupled to the transistor 530 and the first output terminal of the buffer circuitry 502. The second terminal of the transistor 532 is coupled to the auxiliary output terminal, which supplies the auxiliary output voltage. The control terminal of the transistor 532 is coupled to the capacitor 520 and the transistor 528.

The current source circuitry 534 has a first terminal and a second terminal. The first terminal of the current source circuitry 534 is coupled to the supply terminal, which supplies the high-side supply voltage. The second terminal of the current source circuitry 534 is coupled to the transistors 536, 550. In the example of FIG. 5, the current source circuitry 534 is structured to represent the bias currents from the current mirror circuitry 412, 416. Also, the current source circuitry 534 is structured as bias circuitry, which uses a bias current to facilitate the buffer circuitry 504 being in an operational state. Alternatively, as shown in FIGS. 4A and 4B, the current source circuitry 534 may be external to the buffer circuitry 504.

The transistor 536 has a first terminal, a second terminal, and a control terminal. The first and control terminals of the transistor 536 are coupled to the current source circuitry 534 and the transistor 550. The second terminal of the transistor 536 is coupled to the transistor 538. The transistor 538 has a first terminal, a second terminal, and a control terminal. The first terminal of the transistor 538 is coupled to the transistor 536. The second terminal of the transistor 538 is coupled to the common terminal, which supplies the common emitter voltage. The control terminal of the transistor 538 is coupled to the input terminal of the buffer circuitry 504, the transistor 540, and the capacitors 546, 548.

The transistor 540 has a first terminal, a second terminal, and a control terminal. The first terminal of the transistor 540 is coupled to the auxiliary output terminal, which supplies the auxiliary output voltage. The second terminal of the transistor 540 is coupled to the transistor 542. The control terminal of the transistor 540 is coupled to the input terminal of the buffer circuitry 504, the transistor 538, and the capacitors 546, 548. The transistor 542 has a first terminal, a second terminal, and a control terminal. The first terminal of the transistor 542 is coupled to the transistor 540. The second and control terminals of the transistor 542 are coupled to the current source circuitry 544 and the transistor 554.

The current source circuitry 544 has a first terminal and a second terminal. The first terminal of the current source circuitry 544 is coupled to the transistors 542, 554. The second terminal of the current source circuitry 544 is coupled to the common terminal, which supplies the common emitter voltage. In the example of FIG. 5, the current source circuitry 544 is structured to represent the bias currents from the current mirror circuitry 424, 428. Also, the current source circuitry 544 is structured as bias circuitry, which uses a bias current to facilitate the buffer circuitry 504 being in an operational state. Alternatively, as shown in FIGS. 4A and 4B, the current source circuitry 544 may be external to the buffer circuitry 504.

The capacitor 546 has a first terminal and a second terminal. The first terminal of the capacitor 546 is coupled to the input terminal of the buffer circuitry 504, the transistors 538, 540, and the capacitor 548. The second terminal of the capacitor 546 is coupled to the transistors 556, 558 and the first output terminal of the buffer circuitry 504. The capacitor 548 has a first terminal and a second terminal. The first terminal of the capacitor 548 is coupled to the input terminal of the buffer circuitry 504, the transistors 538, 540, and the capacitor 546. The second terminal of the capacitor 548 is coupled to the transistors 556, 560.

The transistor 550 has a first terminal, a second terminal, and a control terminal. The first terminal of the transistor 550 is coupled to the auxiliary output terminal, which supplies the auxiliary output voltage. The second terminal of the transistor 550 is coupled to the transistor 552. The control terminal of the transistor 550 is coupled to the current source circuitry 534 and the transistor 536. The transistor 552 has a first terminal, a second terminal, and a control terminal. The first terminal of the transistor 552 is coupled to the transistor 550. The second terminal of the transistor 552 is coupled to the transistor 554. The control terminal of the transistor 552 is coupled to the transistor 556. The transistor 554 has a first terminal, a second terminal, and a control terminal. The first terminal of the transistor 554 is coupled to the transistor 552. The second terminal of the transistor 554 is coupled to the common terminal, which supplies the common emitter voltage. The control terminal of the transistor 554 is coupled to the transistor 542 and the current source circuitry 544. The transistor 556 has a first terminal, a second terminal, and a control terminal. The first terminal of the transistor 556 is coupled to the capacitor 546, the transistor 558, and the first output terminal of the buffer circuitry 504. The second terminal of the transistor 556 is coupled to the capacitor 548 and the transistor 560. The control terminal of the transistor 556 is coupled to the transistor 552.

The transistor 558 has a first terminal, a second terminal, and a control terminal. The first terminal of the transistor 558 is coupled to the auxiliary output terminal, which supplies the auxiliary output voltage. The second terminal of the transistor 558 is coupled to the transistor 560 and the second output terminal of the buffer circuitry 504. The control terminal of the transistor 558 is coupled to the capacitor 546, the transistor 556, and the second output terminal of the buffer circuitry 504. The transistor 560 has a first terminal, a second terminal, and a control terminal. The first terminal of the transistor 560 is coupled to the transistor 558 and the first output terminal of the buffer circuitry 504. The second terminal of the transistor 560 is coupled to the common terminal, which supplies the common emitter voltage. The control terminal of the transistor 560 is coupled to the capacitor 548 and the transistor 556.

In the example of FIG. 5, the transistors 508, 512, 522, 528, 530, 536, 540, 550, 556, 558 are NPN BJTs. Alternatively, the transistors 508, 512, 522, 528, 530, 536, 540, 550, 556, 558 may be n-channel FETs, n-channel IGBTs, n-channel JFETs, n-channel MOSFETs, or, with slight modifications, p-type equivalent devices. In the example of FIG. 5, the transistors 510, 514, 524, 526, 532, 538, 542, 552, 554, 560 are PNP BJTs. Alternatively, the transistors 510, 514, 524, 526, 532, 538, 542, 552, 554, 560 may be p-channel FETs, p-channel IGBTs, p-channel JFETs, p-channel MOSFETs, or, with slight modifications, N-type equivalent devices. The transistors 508, 510, 512, 514, 522, 524, 526, 528, 530, 532, 536, 538, 540, 542, 550, 552, 554, 556, 558, 560 may be depletion mode devices, drain-extended devices, enhancement mode devices, natural transistors or other type of device structure transistors. Furthermore, the transistors 508, 510, 512, 514, 522, 524, 526, 528, 530, 532, 536, 538, 540, 542, 550, 552, 554, 556, 558, 560 may be implemented in/over a silicon substrate (Si), a silicon carbide substrate (SiC), a gallium nitride substrate (GaN) or a gallium arsenide substrate (GaAs).

FIG. 6 is a schematic diagram of example amplifier circuitry 600, which is yet another example of the amplifier circuitry 108, 200 of FIGS. 1 and 2. In the example of FIG. 6, the amplifier circuitry 600 includes input stage circuitry 602 and output stage circuitry 604. The example input stage circuitry 602 of FIG. 6 includes example input buffer circuitry 606, a first example transistor 608, first example bootstrap buffer circuitry 610, first example divider circuitry 612 a second example transistor 614, second example bootstrap buffer circuitry 616, second example divider circuitry 618, a third example transistor 620, third example bootstrap buffer circuitry 622, third example divider circuitry 624, a fourth example transistor 626, fourth example bootstrap buffer circuitry 628, and fourth example divider circuitry 630. The example buffer circuitry 606 of FIG. 6 includes first example buffer circuitry 632, an example resistor 634, and second example buffer circuitry 636. The example divider circuitry 612 of FIG. 6 includes a first example resistor 638 and a second example resistor 640. The example divider circuitry 618 of FIG. 6 includes a first example resistor 642 and a second example resistor 644. The example divider circuitry 624 of FIG. 6 includes a first example resistor 646 and a second example resistor 647. The example divider circuitry 630 of FIG. 6 includes a first example resistor 648 and a second example resistor 649.

The example output stage circuitry 604 of FIG. 6 includes first example current mirror circuitry 650, a first example transistor 652, second example current mirror circuitry 654, a second example transistor 656, an example capacitor 658, example pre-driver circuitry 660, a third example transistor 662, a fourth example transistor 664, first example bootstrap buffer circuitry 668, first example divider circuitry 670, a fifth example transistor 672, a sixth example transistor 674, second example bootstrap buffer circuitry 676, and second example divider circuitry 678. The example pre-driver circuitry 660 of FIG. 6 includes example buffer circuitry 680, a first example transistor 682, and a second example transistor 684. The example divider circuitry 670 of FIG. 6 includes a first example resistor 686 and a second example resistor 688. The example divider circuitry 678 of FIG. 6 includes a first example resistor 690 and a second example resistor 692.

The input stage circuitry 602 has a first terminal, a second terminal, a first input terminal, a second input terminal, a first output terminal, and a second output terminal. The first terminal of the input stage circuitry 602 is coupled to the supply terminal, which supplies the high-side supply voltage. The second terminal of the input stage circuitry 602 is coupled to the common terminal, which supplies the high-side supply voltage. The first input terminal of the input stage circuitry 602 (also referred to as the non-inverting input terminal) is structured to be coupled to external circuitry, which supplies a first input voltage (V_{IN+}). The second input terminal of the input stage circuitry 602 (also referred to as the inverting input terminal) is structured to be coupled to external circuitry, which supplies a second input voltage (V_{IN-}). The first and second output terminals of the input stage circuitry 602 are coupled to the output stage circuitry 604. The input stage circuitry 602 is another example of the input stage circuitry 116, 206, 300 of FIGS. 1, 2, and 3. However, the input stage circuitry 602 includes additional circuitry to structure both the first and second input terminals as high impedance terminals.

The output stage circuitry 604 has a first terminal, a second terminal, a first input terminal, a second input terminal, and an output terminal. The first terminal of the output stage circuitry 604 is coupled to the supply terminal, which supplies the high-side supply voltage. The second terminal of the output stage circuitry 604 is coupled to the common terminal, which supplies the common emitter terminal. The first and second input terminals of the output stage circuitry 604 are coupled to the input stage circuitry 602. The output terminal of the output stage circuitry 604 is structured to be coupled to a load, such as the capacitive load 112 of FIG. 1. The output stage circuitry 604 is another example of the output stage circuitry 120, 208, 400 of FIGS. 1, 2, 4A, and 4B.

The buffer circuitry 606 has a first terminal, a second terminal, a third terminal, a fourth terminal, a fifth terminal, and a sixth terminal. The first terminal of the buffer circuitry 606 is coupled to the first input terminal of the input stage circuitry 602, which supplies the first voltage. The second terminal of the buffer circuitry 606 is coupled to the second input terminal of the input stage circuitry 602, which supplies the second voltage. The third terminal of the buffer circuitry 606 is coupled to the transistor 608. The fourth terminal of the buffer circuitry 606 is coupled to the transistor 614. The fifth terminal of the buffer circuitry 606 is coupled to the transistor 620. The sixth terminal of the buffer circuitry 606 is coupled to the transistor 626. In the example of FIG. 6, the buffer circuitry 606 is an example of the buffer circuitry 124, 210 of FIG. 1 where both terminals of the buffer circuitry 606, which are coupled to the input terminals of the input stage circuitry 602, are high-impedance terminals.

The transistor 608 has a first terminal, a second terminal, and a control terminal. The first terminal of the transistor 608 is coupled to the supply terminal, which supplies the high-side supply voltage. The second terminal of the transistor 608 is coupled to the buffer circuitry 606. The control terminal of the transistor 608 is coupled to the buffer circuitry 610. The buffer circuitry 610 has a first terminal and a second terminal. The first terminal of the buffer circuitry 610 is coupled to the transistor 608. The second terminal of the buffer circuitry 610 is coupled to the divider circuitry 612. The divider circuitry 612 has a first terminal, a second terminal, and a control terminal. The first terminal of the divider circuitry 612 is coupled to the supply terminal, which supplies the high-side supply voltage. The second terminal of the divider circuitry 612 is coupled to the buffer circuitry 610. The third terminal of the divider circuitry 612 is coupled to the divider circuitry 618.

The transistor 614 has a first terminal, a second terminal, and a control terminal. The first terminal of the transistor 614 is coupled to the buffer circuitry 606. The second terminal of the transistor 614 is coupled to the common terminal, which supplies the common emitter voltage. The control terminal of the transistor 614 is coupled to the buffer circuitry 616. The buffer circuitry 616 has a first terminal and a second terminal. The first terminal of the buffer circuitry 616 is coupled to the transistor 614. The second terminal of the buffer circuitry 616 is coupled to the divider circuitry 618. The divider circuitry 618 has a first terminal, a second terminal, and a third terminal. The first terminal of the divider circuitry 618 is coupled to the divider circuitry 612. The second terminal of the divider circuitry 618 is coupled to the buffer circuitry 616. The third terminal of the divider circuitry 618 is coupled to the common terminal, which supplies the common emitter voltage.

The transistor 620 is coupled to the output stage circuitry 604, the buffer circuitry 606, and the buffer circuitry 622. The transistor 620 is another example of the transistors 128, 212 of FIGS. 1 and 2. The buffer circuitry 622 is coupled to the transistor 620 and the divider circuitry 624. The buffer circuitry 622 is another example of the buffer circuitry 132, 214, 308 of FIGS. 1, 2, and 3. The divider circuitry 624 is coupled to the buffer circuitry 622, the divider circuitry 630, and the supply terminal, which supplies the high-side supply voltage. The divider circuitry 624 is another example of the divider circuitry 136, 216, 310 of FIGS. 1, 2, and 3.

The transistor 626 is coupled to the output stage circuitry 604, the buffer circuitry 606, and the buffer circuitry 628. The transistor 626 is another example of the transistors 140, 218 of FIGS. 1 and 2. The buffer circuitry 628 is coupled to the transistor 626 and the divider circuitry 630. The buffer circuitry 628 is another example of the buffer circuitry 144, 220, 308 of FIGS. 1, 2, and 3. The divider circuitry 630 is coupled to the divider circuitry 624, the buffer circuitry 628, and the common terminal, which supplies the common emitter voltage. The divider circuitry 630 is another example of the divider circuitry 148, 222, 318 of FIGS. 1, 2, and 3.

The buffer circuitry 632 has a first terminal, second terminal, a third terminal, and a fourth terminal. The first terminal of the buffer circuitry 632 is coupled to the first input terminal of the input stage circuitry 602. The second terminal of the buffer circuitry 632 is coupled to the resistor 634. The third terminal of the buffer circuitry 632 is coupled to the transistor 608. The fourth terminal of the buffer circuitry 632 is coupled to the transistor 614. The resistor 634 has a first terminal and a second terminal. The first terminal of the resistor 634 is coupled to the buffer circuitry 632. The second terminal of the resistor 634 is coupled to the buffer circuitry 636. The buffer circuitry 636 has a first terminal, second terminal, a third terminal, and a fourth terminal. The first terminal of the buffer circuitry 636 is coupled to the resistor 634. The second terminal of the buffer circuitry 636 is coupled to the second input terminal of the input stage circuitry 602. The third terminal of the buffer circuitry 636 is coupled to the transistor 620. The fourth terminal of the buffer circuitry 636 is coupled to the transistor 626.

The resistor 638 is coupled to buffer circuitry 610, the divider circuitry 618, and the supply terminal, which supplies the high-side supply voltage. The resistor 638 is another example of the resistors 230, 342 of FIGS. 2 and 3. The resistor 640 is coupled to the buffer circuitry 610, the divider circuitry 618, and the resistor 638. The resistor 640 is another example of the resistors 232, 346 of FIGS. 2 and 3.

The resistor 642 is coupled to the divider circuitry 612, the buffer circuitry 616, and the resistor 644. The resistor 642 is another example of the resistors 240, 364 of FIGS. 2 and 3. The resistor 644 is coupled to the buffer circuitry 616, the resistor 642, and the common terminal, which supplies the common emitter voltage. The resistor 644 is another example of the resistors 242, 368 of FIGS. 2 and 3.

The resistor 646 is coupled to buffer circuitry 622, the divider circuitry 630, and the supply terminal, which supplies the high-side supply voltage. The resistor 646 is another example of the resistors 230, 342 of FIGS. 2 and 3. The resistor 647 is coupled to the buffer circuitry 622, the divider circuitry 630, and the resistor 646. The resistor 647 is another example of the resistors 232, 346 of FIGS. 2 and 3.

The resistor 648 is coupled to the divider circuitry 624, the buffer circuitry 628, and the resistor 649. The resistor 648 is another example of the resistors 240, 364 of FIGS. 2 and 3. The resistor 649 is coupled to the buffer circuitry 628, the resistor 648, and the common terminal, which supplies the common emitter voltage. The resistor 649 is another example of the resistors 242, 368 of FIGS. 2 and 3.

The current mirror circuitry 650 is coupled to the input stage circuitry 602, the transistors 652, 662, and the supply terminal, which supplies the high-side supply voltage. The current mirror circuitry 650 is another example of the current mirror circuitry 152, 243, 402 of FIGS. 1, 2, and 4. The transistor 652 is coupled to the current mirror circuitry 650, the transistors 656, 662, 664, the capacitor 658, the pre-driver circuitry 660, and the buffer circuitry 668. The transistor 652 is another example of the transistors 156, 244 of FIGS. 1 and 2.

The current mirror circuitry 654 is coupled to the input stage circuitry 602, the transistors 656, 672, and the common terminal, which supplies the common emitter voltage. The current mirror circuitry 654 is another example of the current mirror circuitry 654 of FIGS. 160, 245, 404 of FIGS. 1, 2, and 4A. The transistor 656 is coupled to the current mirror circuitry 654, the transistors 652, 672, 674, the capacitor 658, the pre-driver circuitry 660, and the buffer circuitry 676. The transistor 656 is another example of the transistors 164, 246 of FIGS. 1 and 2.

The capacitor 658 is coupled to the transistors 652, 656, the pre-driver circuitry 660, and the common terminal, which supplies the common potential. The capacitor 658 is an example of the capacitor 247 of FIG. 2. The pre-driver circuitry 660 is coupled to the transistors 652, 656, 662, 664, 672, 674, the capacitor 658, and the output terminal of the output stage circuitry 604. The pre-driver circuitry 660 is another example of the pre-driver circuitry 168, 248, 406 of FIGS. 1, 2, and 4A.

The transistor 662 is coupled to the current mirror circuitry 650, the transistors 652, 664, the pre-driver circuitry 660, and the buffer circuitry 668. The transistor 662 is another example of the transistor 407 of FIG. 4A. The transistor 664 is coupled to the transistors 652, 662, the pre-driver circuitry 660, the buffer circuitry 668, and the supply terminal, which supplies the high-side supply voltage. The transistor 664 is another example of the transistors 251, 410 of FIGS. 2 and 4A. The buffer circuitry 668 is coupled to the transistors 652, 662, 664 and the divider circuitry 670. The buffer circuitry 668 is another example of the buffer circuitry 176, 252, 414, 502, of FIGS. 1, 2, 4B, and 5. The divider circuitry 670 is coupled to the buffer circuitry 668, the divider circuitry 678, and the supply terminal, which supplies the high-side supply voltage. The divider circuitry 678 is another example of the divider circuitry 180, 253, 418 of FIGS. 1, 2, and 4B.

The transistor 672 is coupled to the current mirror circuitry 654, the transistor 656, 674, the pre-driver circuitry 660, and the buffer circuitry 676. The transistor 672 is an example of the transistor 407 of FIG. 4A. The transistor 674 is coupled to the transistors 656, 672, the pre-driver circuitry 660, the buffer circuitry 676, and the common terminal, which supplies the common emitter voltage. The transistor 674 is another example of the transistor 256, 422 of FIGS. 2 and 4A. The buffer circuitry 676 is coupled to the transistors 656, 672, 674 and the divider circuitry 678. The buffer circuitry 676 is another example of the buffer circuitry 188, 257, 426, 504 of FIGS. 1, 2, 4B, and 5. The divider circuitry 678 is coupled to the divider circuitry 670, the buffer circuitry 676, and the common terminal, which supplies the common emitter voltage. The divider circuitry 678 is another example of the divider circuitry 192, 258, 430 of FIGS. 1, 2, and 4B.

The buffer circuitry 680 is coupled to the transistors 652, 656, 662, 672, 682, 684 and the capacitor 658. The buffer circuitry 680 is an example of the buffer circuitry 259 of FIG. 2. The transistor 682 is coupled to the transistors 664, 684, the buffer circuitry 680, and the output terminal of the output stage circuitry 604. The transistor 682 is another example of the transistor 261, 460 of FIGS. 2 and 4A. The transistor 684 is coupled to the transistors 674, 682, the buffer circuitry 680, and the output terminal of the output stage circuitry 604. The transistor 684 is another example of the transistor 265, 463 of FIGS. 2 and 4A.

The resistor 686 is coupled to the buffer circuitry 668, the divider circuitry 678, the resistor 688, and the supply terminal, which supplies the high-side supply voltage. The resistor 686 is another example of the resistors 270, 468 of FIGS. 2 and 4B. The resistor 688 is coupled to the buffer circuitry 668, the divider circuitry 678, and the resistor 686. The resistor 688 is another example of the resistors 271, 469 of FIGS. 2 and 4B.

The resistor 690 is coupled to the divider circuitry 670, the buffer circuitry 676, and the resistor 692. The resistor 690 is another example of the resistors 276, 476 of FIGS. 2 and 4B. The resistor 692 is coupled to the buffer circuitry 676, the resistor 690, and the common terminal, which supplies the common emitter voltage. The resistor 692 is another example of the resistor 277, 478 of FIGS. 2 and 4B.

In the example of FIG. 6, the transistors 608, 620, 656, 664, 672, 682 are NPN BJTs. Alternatively, the transistors 608, 620, 656, 664, 672, 682 may be n-channel FETs, n-channel IGBTs, n-channel JFETs, n-channel MOSFETs, or, with slight modifications, p-type equivalent devices. In the example of FIG. 6, the transistors 614, 626, 652, 662, 674, 684 are PNP BJTs. Alternatively, the transistors 614, 626, 652, 662, 674, 684 may be p-channel FETs, p-channel IGBTs, p-channel JFETs, p-channel MOSFETs, or, with slight modifications, N-type equivalent devices. The transistors 608, 614, 620, 626, 652, 656, 662, 664, 672, 674, 682, 684 may be depletion mode devices, drain-extended devices, enhancement mode devices, natural transistors or other type of device structure transistors. Furthermore, the transistors 608, 614, 620, 626, 652, 656, 662, 664, 672, 674, 682, 684 may be implemented in/over a silicon substrate (Si), a silicon carbide substrate (SiC), a gallium nitride substrate (GaN) or a gallium arsenide substrate (GaAs).

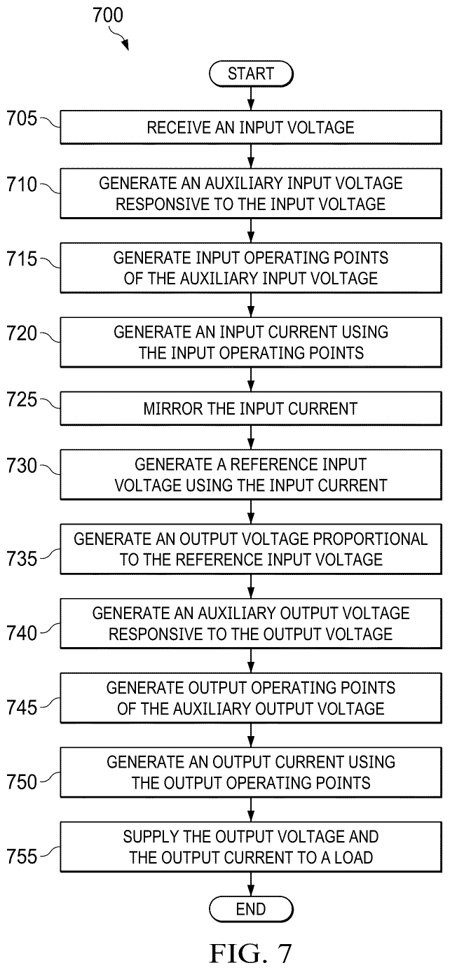

FIG. 7 is a flowchart representative of example operations 700 that may be at least one of executed, instantiated, or performed to implement the input stage circuitry 116, 206, 300, 602 of FIGS. 1, 2, 3, and 6, the output stage circuitry 120, 208, 400, 604 of FIGS. 1, 2, 4A, 4B, and 6, or more generally the amplifier circuitry 108, 200, 600 of FIGS. 1, 2, and 6. The example operations 700 of FIG. 7 begin at Block 705, at which, the amplifier circuitry 108, 200, 600 receives an input voltage. In some examples, the amplifier circuitry 108, 200, 600 receives the input voltage as the voltage difference between the non-inverting input and the inverting input terminals of the buffer circuitry 124, 210, 302, 606 of FIGS. 1, 2, 3, and 6. In example operations, the input voltage causes the buffer circuitry 124, 210, 302, 606 to source and sink currents that are proportional to the input voltage.

The input stage circuitry 116, 206, 300, 602 generate an auxiliary input voltage responsive to the input voltage. (Block 710). In some examples, the buffer circuitry 124, 210, 302, 606 generate the auxiliary input voltage as a replica of the input voltage using the currents that are proportional to the input voltage. For example, the buffer circuitry 302 controls the transistors 304, 312 of FIG. 3 to set the auxiliary voltage. In such examples, the auxiliary voltage is approximately equal to the input voltage.

The divider circuitry 136, 148, 216, 222, 310, 318, 612, 618, 624, 630 of FIGS. 1, 2, 3, and 6 generate input operating points of the auxiliary input voltage. (Block 715). In some examples, the divider circuitry 136, 148, 216, 222, 310, 318, 612, 618, 624, 630 generate the input operating points as input operating voltages between the auxiliary input voltage and one of the high-side supply voltage or the low-side supply voltage. In such examples, the divider circuitry 136, 148, 216, 222, 310, 318, 612, 618, 624, 630 supply the input operating voltages to the buffer circuitry 132, 144, 214, 220, 308, 316, 610, 616, 622, 628 of FIGS. 1, 2, 3, and 6, which buffer the input operating voltages.

In example operation, the divider circuitry 136, 216, 310, 612, 624 generate a high-side input operating point as a first operating voltage that is approximately, preferably exactly, halfway between the auxiliary voltage and the high-side supply voltage. For example, in response to the high-side supply voltage being thirty volts and the input voltage being twenty-five volts, the divider circuitry 136, 216, 310, 612, 624 set the first operating voltage at twenty-seven and a half volts (V). In another example, in response to the high-side supply voltage being thirty volts and the input voltage being negative two volts, the divider circuitry 136, 216, 310, 612, 624 set the first operating voltage at fourteen volts.

In such example operations, the divider circuitry 148, 222, 318, 618, 630 generate a low-side operating point as a second operating voltage that is approximately, preferably exactly, halfway between the auxiliary voltage and the common emitter voltage. For example, in response to the low-side supply voltage being negative thirty volts and the input voltage being twenty-five volts, the divider circuitry 148, 222, 318, 618, 630 set the second operating voltage at negative two and a half volts. In another example, in response to the low-side supply voltage being negative thirty volts and the input voltage being negative twenty-five volts, the divider circuitry 148, 222, 318, 618, 630 set the second operating voltage at negative twenty-seven and a half volts.

The transistors 128, 140, 212, 218, 306, 314, 620, 626 of FIGS. 1, 2, 3, and 6 generate an input current using the input operating points. (Block 720). In some examples, the buffer circuitry 132, 144, 214, 220, 308, 316, 610, 616, 622, 628 control the transistors 128, 140, 212, 218, 306, 314, 620, 626 by buffering the input operating voltages from the divider circuitry 136, 148, 216, 222, 310, 318, 612, 618, 624, 630. In such examples, the transistors 128, 140, 212, 218, 306, 314, 620, 626 generate one of the high-side input current or the low-side input currents responsive to the operating voltages from the buffer circuitry 132, 144, 214, 220, 308, 316, 610, 616, 622, 628.

Advantageously, the transistors 128, 140, 212, 218, 306, 314, 620, 626 generate the high-side input current and the low-side input currents using the input operating voltages, which are dependent on the relationship of the input voltage to the high-side supply voltage and the common emitter voltage. Advantageously, the buffer circuitry 132, 144, 214, 220, 308, 316, 610, 616, 622, 628 is driven by the auxiliary input voltage and one of the high-side supply voltage or the low-side supply voltage, which decreases the response time in bootstrapping base voltages for the stacking cascode transistors.

The current mirror circuitry 152, 160, 243, 245, 402, 404, 650, 654 of FIGS. 1, 2, 4A, and 6 mirrors the input current. (Block 725). In some examples, the current mirror circuitry 152, 243, 402, 650 mirrors the high-side input current from the transistors 128, 212, 306, 620 and the current mirror circuitry 160, 245, 404, 654 mirrors the low-side input current from the transistors 140, 218, 314, 626. In such examples, the current mirror circuitry 152, 160, 243, 245, 402, 404, 650, 654 supply the input currents to the transistors 156, 164, 170, 182, 244, 246, 249, 254, 403, 405, 407, 408, 419, 420, 652, 656 of FIGS. 1, 2, 4A, and 6.

The output stage circuitry 120, 208, 400, 604 generates a reference input voltage using the input current. (Block 730). In some examples, the capacitors 247, 453, 457, 658 of FIGS. 2, 4A, and 6 generate the reference input voltage responsive to the input currents. For example, the capacitors 247, 658 generate the reference input voltage responsive to the input currents from the transistors 244, 246, 652, 656. In another example, the transistors 403, 405, 446, 447 generate the reference input voltages by controlling current paths that supply current to the capacitors 453, 457. Such a control of current paths may be referred to as cascode control. In such an example, the transistors 403, 405, 446, 447 control the transistors 448, 449, which create current paths that control the transistors 452, 456 that set the reference input voltage across the capacitors 453, 457. Also, the output stage circuitry 120, 208, 400, 604 may be illustrated with the capacitors 247, 453, 457, 658 as individual components (e.g., in FIGS. 2 and 6) or as part of another component (e.g., in FIG. 4A).

The pre-driver circuitry 168, 248, 406, 660 of FIGS. 1, 2, 4A, and 6 generates an output voltage proportional to the reference input voltage. (Block 735). In some examples, the buffer circuitry 259 controls the transistors 260, 264 based on the reference input voltage. In such examples, the transistors 260, 264 further control the transistors 261, 265, which set the output voltage. In other examples, the current paths through the pre-driver circuitry 406 sets the reference input voltage across the capacitors 453, 457. In such examples, the voltages of the capacitors 453, 457 control the transistors 460, 463, which generate the output voltage by supplying current to the resistors 461, 462.

The output stage circuitry 120, 208, 400, 604 generates an auxiliary output voltage responsive to the output voltage. (Block 740). In some examples, the output stage circuitry 120, 208, 400, 604 uses the reference input voltage and transistors to generate the auxiliary output voltage by mirroring currents through transistors that are controlled responsive to the pre-driver circuitry 168, 248, 406, 660 generating a gate control voltage. For example, the reference input voltage controls the transistors 448, 449 of FIG. 4A, which drive current through the transistors 450, 451, 452, 454, 455, 456 of FIG. 4A to control the transistors 431, 434 of FIG. 4B and the resistors 432, 433 of FIG. 4B. In such an example, the transistors 431, 434 and the resistors 432, 433 generate the auxiliary output voltage by mirroring the currents of the transistors 460, 463 and the resistors 461, 462 using the voltage at the control terminals of the transistors 460, 463, which control the output voltage. Also, the capacitors 453, 457 of FIG. 4A form a feed-forward current path to the output of the output stage circuitry 400, which compensates for phase loss resulting from delays at high frequencies.

The divider circuitry 180, 192, 253, 258, 418, 430, 670, 678 of FIGS. 1, 2, 4B, and 6 generate output operating points of the auxiliary output voltage. (Block 745). In some examples, the divider circuitry 180, 192, 253, 258, 418, 430, 670, 678 generate the output operating points as output operating voltages between the auxiliary output voltage and one of the high-side supply voltage or the low-side supply voltage. In such examples, the divider circuitry 180, 192, 253, 258, 418, 430, 670, 678 supply the output operating voltages to the buffer circuitry 176, 188, 252, 257, 414, 426, 502, 504, 668, 676 of FIGS. 1, 2, 4B, 5, and 6, which buffer the output operating voltages.

In example operation, the divider circuitry 180, 253, 418, 670 generates a first output operating point as a first output operating voltage that is approximately halfway between the auxiliary output voltage and the high-side supply voltage. For example, in response to the high-side supply voltage being thirty volts and the output voltage being twenty-five volts, the divider circuitry 180, 253, 418, 670 set the first output operating voltage at twenty-seven and a half volts (V). In another example, in response to the high-side supply voltage being thirty volts and the output voltage being negative twenty-five volts, the divider circuitry 180, 253, 418, 670 set the first output operating voltage at two and a half volts.

In such example operations, the divider circuitry 192, 258, 430, 678 generate a second output operating point as a second output operating voltage that is approximately halfway between the auxiliary output voltage and the low-side supply voltage. For example, in response to the low-side supply voltage being negative thirty volts and the output voltage being twenty-five volts, the divider circuitry 192, 258, 430, 678 set the second output operating voltage at negative two and a half volts. In another example, in response to the low-side supply voltage being negative thirty volts and the output voltage being negative twenty-five volts, the divider circuitry 192, 258, 430, 678 set the second output operating voltage at negative twenty-seven and a half volts.

The transistors 172, 184, 251, 256, 261, 265, 410, 422, 460, 463, 664, 674, 682, 684 of FIGS. 1, 2, 4A, and 6 generate an output current using the output operating points. (Block 750). In some examples, the buffer circuitry 176, 188, 252, 257, 414, 426, 502, 504, 668, 676 control the transistors 172, 184, 251, 256, 261, 265, 410, 422, 460, 463, 664, 674, 682, 684 by buffering the output operating voltages from the divider circuitry 180, 192, 253, 258, 418, 430, 670, 678. In such examples, the transistors 172, 184, 251, 256, 261, 265, 410, 422, 460, 463, 664, 674, 682, 684 generate one of the high-side output current or the low-side output current responsive to the output operating voltages from the buffer circuitry 176, 188, 252, 257, 414, 426, 502, 504, 668, 676.

Advantageously, the transistors 172, 184, 251, 256, 261, 265, 410, 422, 460, 463, 664, 674, 682, 684 generate the high-side output current and the low-side output current using the output operating voltages, which are dependent on the relationship of the output voltage to the high-side supply voltage and the low-side supply voltage. Advantageously, the buffer circuitry 176, 188, 252, 257, 414, 426, 502, 504, 668, 676 is driven by the auxiliary output voltage and one of the high-side supply voltage or the low-side supply voltage, which decreases the response time in generating the output current.

The pre-driver circuitry 168, 248, 406, 660 supplies the output voltage and the output current to a load. (Block 755). In some examples, the pre-driver circuitry 168, 248, 406, 660 supply the output voltage and output current to the capacitive load 112 of FIG. 1. Advantageously, the buffer circuitry 176, 188, 252, 257, 414, 426, 502, 504, 668, 676 increase the output current, increase the slew rate, and support increasingly high the output voltages of the amplifier circuitry 108, 200, 600.

Although example methods are described with reference to the flowchart illustrated in FIG. 7, many other methods of implementing the input stage circuitry 116, 206, 300, 602 of FIGS. 1, 2, 3, and 6, the output stage circuitry 120, 208, 400, 604 of FIGS. 1, 2, 4A, 4B, and 6, or more generally the amplifier circuitry 108, 200, 600 of FIGS. 1, 2, and 6 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An amplifier comprising:
first stage circuitry including:
first buffer circuitry having a first terminal and a second terminal;
second buffer circuitry having a first terminal and a second terminal;
third buffer circuitry having a first terminal and a second terminal, the first terminal of the third buffer circuitry coupled to the first terminal of the second buffer circuitry;
a first transistor having a first terminal, a second terminal and a control terminal, the first terminal of the first transistor coupled to the first terminal of the first buffer circuitry, the control terminal of the first transistor coupled to the second terminal of the second buffer circuitry;
a second transistor having a first terminal, a second terminal, and a control terminal, the first terminal of the second transistor coupled to the second terminal of the first buffer circuitry, the control terminal of the second transistor coupled to the second terminal of the third buffer circuitry; and
second stage circuitry having a first terminal and a second terminal, the first terminal of the second stage circuitry coupled to the second terminal of the first transistor, the second terminal of the second stage circuitry coupled to the second terminal of the second transistor.

2. The amplifier of claim 1, wherein the second stage circuitry includes:
current mirror circuitry having a first terminal and a second terminal, the first terminal of the current mirror circuitry coupled to the second terminal of the first transistor;
pre-driver circuitry having a terminal;
fourth buffer circuitry having a terminal; and
a third transistor having a first terminal, a second terminal, and a control terminal, the first terminal of the third transistor is coupled to the second terminal of the current mirror circuitry, the second terminal of the third transistor is coupled to the terminal of the pre-driver circuitry, and the control terminal of the third transistor is coupled to the terminal of the fourth buffer circuitry.

3. The amplifier of claim 2, wherein the terminal of the fourth buffer circuitry is a first terminal, the fourth buffer circuitry further having a second terminal and a third terminal, the amplifier further comprising divider circuitry having a first terminal and a second terminal, the first terminal of the divider circuitry coupled to the second terminal of the fourth buffer circuitry, and the second terminal of the divider circuitry is coupled to the third terminal of the fourth buffer circuitry.

4. The amplifier of claim 1, wherein the second buffer circuitry further has a third terminal, the third buffer circuitry further has a third terminal, and the amplifier further includes:
first divider circuitry having a first terminal and a second terminal, the first terminal of the first divider circuitry is coupled to the third terminal of the second buffer circuitry; and
second divider circuitry having a first terminal and a second terminal, the first terminal of the second divider circuitry is coupled to the third terminal of the third buffer circuitry, the second terminal of the second divider circuitry is coupled to the first terminal of the second buffer circuitry, the first terminal of the third buffer circuitry, and the second terminal of the first divider circuitry.

5. The amplifier of claim 1, further comprising:
a third transistor having a first terminal, a second terminal, and a control terminal, the first terminal of the third transistor is coupled to the first terminal of the first transistor, the control terminal of the third transistor is coupled to the first terminal of the first buffer circuitry; and
a fourth transistor having a first terminal, a second terminal, and a control terminal, the first terminal of the third transistor is coupled to the first terminal of the second transistor, the second terminal of the fourth transistor is coupled to the first terminal of the second buffer circuitry, the first terminal of the third buffer circuitry, and the second terminal of the third transistor, the control terminal of the fourth transistor is coupled to the second terminal of the first buffer circuitry.

6. The amplifier of claim 1, wherein the second buffer circuitry further has a third terminal and a fourth terminal, the third buffer circuitry further has a third terminal and a fourth terminal, and the amplifier further comprising:
a third transistor having a first terminal, a second terminal, and a control terminal, the first terminal of the third transistor is coupled to the third terminal of the second buffer circuitry, the second terminal of the third transistor is coupled to the third terminal of the third buffer circuitry; and
a fourth transistor having a first terminal, a second terminal, and a control terminal, the first terminal of the fourth transistor is coupled to the fourth terminal of the second buffer circuitry, the second terminal of the fourth transistor is coupled to the fourth terminal of the third buffer circuitry, and the control terminal of the fourth transistor is coupled to the first terminal of the second buffer circuitry, the first terminal of the third buffer circuitry, and the control terminal of the third transistor.

7. The amplifier of claim 1, wherein the first buffer circuitry further has a third terminal, and the amplifier is further comprising:
fourth buffer circuitry having a first terminal and a second terminal, the first terminal of the fourth buffer circuitry is coupled to the third terminal of the first buffer circuitry;
fifth buffer circuitry having a terminal; and
a third transistor having a first terminal and a control terminal, the first terminal of the third transistor is coupled to the second terminal of the fourth buffer circuitry, the control terminal of the third transistor is coupled to the terminal of the fifth buffer circuitry.

8. An amplifier comprising:
first stage circuitry having a first terminal and a second terminal; and
second stage circuitry including:
first current mirror circuitry having a first terminal and a second terminal, the first terminal of the first current mirror circuitry coupled to the first terminal of the first stage circuitry;
second current mirror circuitry having a first terminal and a second terminal, the first terminal of the second current mirror circuitry coupled to the second terminal of the first stage circuitry;
pre-driver circuitry having a terminal;
first buffer circuitry having a first terminal and a second terminal; and
second buffer circuitry having a first terminal and a second terminal, the first terminal of the second buffer circuitry is coupled to the first terminal of the first buffer circuitry;
a first transistor having a first terminal, a second terminal, and a control terminal, the first terminal of the first transistor coupled to the second terminal of the first current mirror circuitry, the control terminal of the first transistor coupled to the second terminal of the first buffer circuitry; and
a second transistor having a first terminal, a second terminal, and a control terminal, the first terminal of the second transistor coupled to the second terminal of the second current mirror circuitry, the second terminal of the second transistor coupled to the terminal of the pre-driver circuitry and the second terminal of the first transistor, the control terminal of the second transistor coupled to the second terminal of the second buffer circuitry.

9. The amplifier of claim 8, wherein the first stage circuitry includes:
third buffer circuitry having a terminal;
fourth buffer circuitry having a terminal; and
a third transistor having a first terminal, a second terminal, and a control terminal, the first terminal of the third transistor is coupled to the first terminal of the first current mirror circuitry, the second terminal of the third transistor is coupled to the terminal of the third buffer circuitry, the control terminal of the third transistor is coupled to the terminal of the fourth buffer circuitry.

10. The amplifier of claim 9, wherein the terminal of the fourth buffer circuitry is a first terminal, the fourth buffer circuitry further having a second terminal and a third terminal, the amplifier further comprising divider circuitry having a first terminal and a second terminal, the first terminal of the divider circuitry coupled to the second terminal of the fourth buffer circuitry, and the second terminal of the divider circuitry is coupled to the third terminal of the fourth buffer circuitry.

11. The amplifier of claim 9, wherein the terminal of the third buffer circuitry is a first terminal, the third buffer circuitry further has a second terminal, and the amplifier further comprising:
fifth buffer circuitry having a first terminal and a second terminal, the first terminal of the fifth buffer circuitry is coupled to the second terminal of the third buffer circuitry;
sixth buffer circuitry having a terminal; and
a fourth transistor having a first terminal and a control terminal, the first terminal of the fourth transistor is coupled to the second terminal of the fifth buffer circuitry, the control terminal of the fourth transistor is coupled to the terminal of the sixth buffer circuitry.

12. The amplifier of claim 8, wherein the first buffer circuitry further has a third terminal, the second buffer circuitry further has a third terminal, and the amplifier further includes:
first divider circuitry having a first terminal and a second terminal, the first terminal of the first divider circuitry is coupled to the third terminal of the first buffer circuitry; and
second divider circuitry having a first terminal and a second terminal, the first terminal of the second divider circuitry is coupled to the third terminal of the second buffer circuitry, the second terminal of the second divider circuitry is coupled to the first terminal of the first buffer circuitry, the first terminal of the second buffer circuitry, and the second terminal of the first divider circuitry.

13. The amplifier of claim 8, wherein the terminal of the pre-driver circuitry is a first terminal, the pre-driver circuitry further has a second terminal and a third terminal, the amplifier further comprising:
a third transistor having a first terminal and a control terminal, the control terminal of the third transistor is coupled to the second terminal of the first buffer circuitry and the control terminal of the first transistor;
a fourth transistor having a first terminal, a second terminal and a control terminal, the first terminal of the fourth transistor is coupled to the first terminal of the third transistor, the control terminal of the fourth transistor is coupled to the second terminal of the pre-driver circuitry;
a fifth transistor having a first terminal, a second terminal, and a control terminal, the first terminal of the fifth transistor is coupled to the first terminal of the first buffer circuitry, the first terminal of the second buffer circuitry, and the second terminal of the fourth transistor, the control terminal of the fifth transistor is coupled to the third terminal of the pre-driver circuitry; and
a sixth transistor having a first terminal and a control terminal, the first terminal of the sixth transistor is coupled to the second terminal of the fifth transistor, the control terminal of the sixth transistor is coupled to the second terminal of the second buffer circuitry and the control terminal of the second transistor.

14. The amplifier of claim 8, further comprising capacitor circuitry having a terminal coupled to the terminal of the pre-driver circuitry, the second terminal of the first transistor, and the second terminal of the second transistor.

15. An apparatus comprising:
input stage circuitry configured to:
generate input operating points of an input voltage; and
generate a reference current based on the input operating points; and
output stage circuitry coupled to the input stage circuitry, the output stage circuitry configured to:
generate a reference voltage based on the reference current;
generate an output voltage based on the reference voltage;
generate output operating points of the output voltage; and
increase an output current of the output voltage responsive to the output operating points.

16. The apparatus of claim 15, wherein the input stage circuitry is further configured to:
receive the input voltage;
generate an auxiliary input voltage responsive to receiving the input voltage; and
generate the input operating points to be half of a difference between the auxiliary input voltage and a supply voltage.

17. The apparatus of claim 15, wherein the output stage circuitry is further configured to:
mirror the reference current to generate a replica of the reference current; and
convert the replica of the reference current to generate the reference voltage.

18. The apparatus of claim 15, wherein the output stage circuitry is further configured to:
generate an auxiliary output voltage responsive to generating the output voltage; and
generate the output operating points to be half of a difference between the auxiliary output voltage and a supply voltage.

19. The apparatus of claim 15, wherein the output stage circuitry is further configured to:
mirror the output current to generate a feedback current; and
dynamically boost the output current using the feedback current.

20. The apparatus of claim 15, wherein the apparatus is an amplifier.
